(19) United States
(12) Patent Application Publication
(10) Pub. No.: US 2026/0010425 A1
(43) Pub. Date: Jan. 8, 2026

(54) MEMORY SYSTEM FOR FAULT ANALYSIS, FAULT ANALYSIS DEVICE, AND FAULT ANALYSIS METHOD

(71) Applicant: SK hynix Inc., Icheon-si (KR)

(72) Inventors: Yong Jun LEE, San Jose, CA (US); Hoiju CHUNG, San Jose, CA (US); Woong Ju JANG, San Jose, CA (US); Eui Sang OH, San Jose, CA (US)

(21) Appl. No.: 18/928,018

(22) Filed: Oct. 26, 2024

Related U.S. Application Data
(60) Provisional application No. 63/667,389, filed on Jul. 3, 2024.

(51) Int. Cl. G06F 11/07

(52) U.S. Cl. CPC G06F 11/079

(57) ABSTRACT

A memory system includes at least one memory device disposed along a first direction and a second direction, configured to include a plurality of cell blocks that share word line drivers with adjacent cell blocks in the first direction, to share bit line sense amplifiers with adjacent cell blocks in the second direction, and to input/output data of the plurality of cell blocks through a plurality of data pads; and a fault analysis device configured to analyze a fault of the memory device by accumulating an error information from the memory device and reflecting device information, including architectural information on the plurality of cell blocks and data input/output information, onto the accumulated error information.

### CROSS-REFERENCE TO RELATED APPLICATION

This patent application claims the benefit of priority under 35 U.S.C. § 119(e) to U.S. Provisional Application No. 63/667,389 filed on Jul. 3, 2024, which is incorporated herein by reference in its entirety.

### BACKGROUND

### 1. Field

Various embodiments of the present disclosure relate to a semiconductor design technology, and more particularly, to a fault analysis device and a memory system for fault analysis.

### 2. Description of the Related Art

The failure of a memory device is one of the main causes of server failure in data centers and the associated downtime. Memory device errors may be classified as correctable errors (CE) or uncorrectable errors (UE). The CE may be corrected by performing an error checking and correction operation, whereas the UE may not be corrected by error checking and correction operation and may cause a system failure. Therefore, various methods for predicting a UE that may occur in a memory system are being studied.

Meanwhile, a method of predicting an occurrence of UE based on the number of occurrences of CEs has been proposed, but the prediction rate of occurrences of UEs become relatively low because the correlation between CE and UE is not high. In addition, a method of predicting an occurrence of UE based on a system address has been proposed, but the actual architecture of memory devices differ by product or by company, so the prediction rate of occurrences of UEs is relatively low.

### SUMMARY

Embodiments of the present disclosure are directed to a fault analysis device capable of analyzing faults by reflecting device information, which includes architectural information and data input/output information of a memory device, onto an error information, and a memory system including the same.

In accordance with an embodiment of the present disclosure, a memory system includes: at least one memory device disposed along a first direction and a second direction, configured to include a plurality of cell blocks that share word line drivers with adjacent cell blocks in the first direction, to share bit line sense amplifiers with adjacent cell blocks in the second direction, and to input/output data of the plurality of cell blocks through a plurality of data pads; and a fault analysis device configured to analyze a fault of the memory device by accumulating an error information from the memory device and reflecting device information, including architectural information on the plurality of cell blocks and data input/output information, onto the accumulated error information.

In accordance with another embodiment of the present disclosure, a fault analysis device includes a memory fault analyzer configured to analyze a fault of a memory device by accumulating an error information from the memory device and reflecting device information including architectural information on a plurality of cell blocks and data input/output information, onto the accumulated error information, the memory device being disposed along a first direction and a second direction, including the plurality of cell blocks that share word line drivers with adjacent cell blocks in the first direction and share bit line sense amplifiers with adjacent cell blocks in the second direction, and inputting/outputting data of the plurality of cell blocks through a plurality of data pads; and a reliability, accessibility, and serviceability (RAS) manager configured to perform an operation of improving a reliability of the memory device based on information on the analyzed fault.

In accordance with yet another embodiment of the present disclosure, a fault analysis method includes accumulating an error information from at least one memory device that is disposed along a first direction and a second direction and includes a plurality of cell blocks that share word line drivers with adjacent cell blocks in the first direction and share bit line sense amplifiers with adjacent cell blocks in the second direction, and that inputs/outputs data of the plurality of cell blocks through a plurality of data pads; checking error locations of data output from the plurality of cell blocks based on the accumulated error information; configuring a physical layout of the plurality of cell blocks based on architectural information of the plurality of cell blocks; and identifying bad cell blocks including the error locations from the physical layout, and generating a fault information on the bad cell blocks according to data input/output information.

According to embodiments of the present invention, the memory system may specify a fault boundary capable of occurring errors by analyzing faults based on the actual architecture of the memory device, and improve the prediction rate of occurrences of UEs by the error correction capability extended by the specified fault boundary. Further, according to embodiments of the present invention, the memory system may reduce the system crash rate and provide optimized reliability, accessibility, and serviceability (RAS) operation due to the improved prediction rate of occurrences of UEs.

These and other features and advantages of the embodiments of the present disclosure will become apparent to those skilled in the art from the following detailed description in conjunction with the following drawings.

### BRIEF DESCRIPTION OF THE DRAWINGS

FIG. 1 is a block diagram illustrating a memory system according to an embodiment of the present disclosure.

FIG. 2 is a diagram illustrating a data input/output operation of a memory device of FIG. 1.

FIG. 3 is a block diagram illustrating a memory device of FIG. 1 according to an embodiment of the present disclosure.

FIGS. 4 and 5 are diagrams illustrating a memory cell array of each bank in FIG. 3.

FIGS. 6A to 6C are diagrams for describing a data input/output operation in a first input/output mode.

FIGS. 7A to 7C are diagrams for describing a data input/output operation in a second input/output mode.

FIGS. 8A to 8C are diagrams illustrating data input/output operations in a third input/output mode.

FIGS. 9A and 9B are diagrams for describing a fault analysis method according to an error location in first to third input/output modes.

FIG. 10 is a detailed block diagram illustrating a memory controller of FIG. 1 according to an embodiment of the present invention.

FIGS. 11A to 11J are diagrams for illustrating operations of a memory fault analyzer according to embodiments of the present disclosure.

FIGS. 12 to 15 are flowcharts for describing a fault analysis operation according to an embodiment of the present disclosure.

FIG. 16 is a block diagram illustrating a memory system including a memory module according to an embodiment of the present disclosure.

FIG. 17 is a block diagram illustrating a memory system including a stacked memory device according to an embodiment of the present disclosure.

FIG. 18 is a block diagram illustrating a mobile system including a memory device according to an embodiment of the present disclosure.

### DETAILED DESCRIPTION

Various embodiments of the present disclosure will be described below in more detail with reference to the accompanying drawings. The embodiments of the present disclosure may, however, be in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

It will be understood that when an element is referred to as being “coupled” or “connected” to another element, it may mean that the two are directly coupled or the two are electrically connected to each other with another circuit or element intervening therebetween. It will be further understood that the terms “comprise”, “include”, “have”, etc. when used in this specification, specify the presence of stated features, numbers, steps, operations, elements, components, and/or combinations of them but do not preclude the presence or addition of one or more other features, numbers, steps, operations, elements, components, and/or combinations thereof. In the present disclosure, the singular forms are intended to include the plural forms as well, unless the context clearly indicates otherwise.

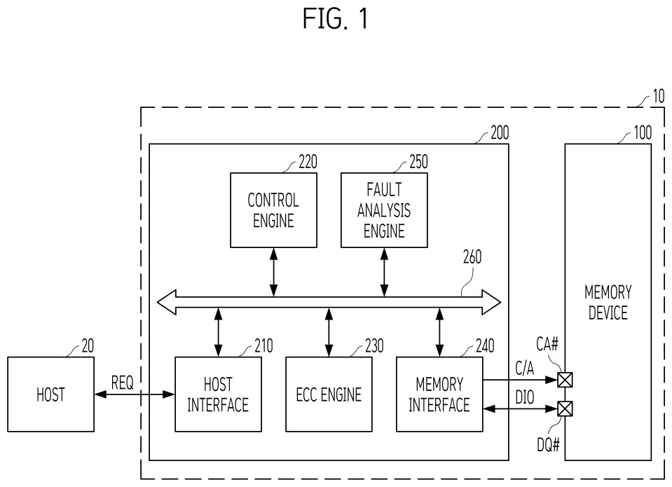

FIG. 1 is a block diagram illustrating a memory system according to an embodiment of the present disclosure.

Referring to FIG. 1, a memory system 10 may include a memory device 100 and a memory controller 200. The memory system 10 may store data under the control of a host 20, such as a cellular phone, a smartphone, an MP3 player, a laptop computer, a desktop computer, a game player, a TV, a tablet PC, or an in-vehicle infotainment system. The host 20 may be an external device of the memory system 10.

The memory controller 200 may control operations of the memory system 10 and control data transfer between the host 20 and the memory device 100. The memory controller 200 may generate a command/address signal C/A according to a request REQ from the host 20 and provide the generated command/address signal C/A to the memory device 100. The memory controller 200 may provide data DIO corresponding to the request REQ from the host 20 to the memory device 100, and provide the data DIO read from the memory device 100 to the host 20. For example, the memory controller 200 may provide a write command, address, and data to the memory device 100 during a write operation. During a read operation, the memory controller 200 may provide a read command and address to the memory device 100 and provide data read from the memory device 100 to the host 20.

The memory device 100 may store the data DIO. The memory device 100 may operate under the control of the memory controller 200. The memory device 100 may include a memory cell array including a plurality of memory cells that store data. The memory device 100 may include dynamic random access memory (DRAM) including dynamic memory cells. In an embodiment, the memory device 100 may be a double data rate synchronous dynamic random access memory (DDR SDRAM), a low power double data rate (LPDDR) type SDRAM, a graphics double data rate (GDDR) SDRAM, a Rambus dynamic random access memory (RDRAM), or others.

The memory device 100 is configured to receive the command/address signal C/A from the memory controller 200 to access an area selected from the memory cell array. That is, the memory device 100 may perform an operation instructed by a command on the area selected by an address. For example, the memory device 100 may perform a write operation (e.g., program operation) to write data DIO to the area selected by the address. During a read operation, the memory device 100 may read data DIO from the area selected by the address.

In memory device 100, command/address pads CA# for receiving the command/address signal C/A and data pads DQ# for receiving the data DIO may be disposed. Although only one command/address pad CA# and one data pad DQ# are illustrated in FIG. 1, the command/address pads CA# and the data pads DQ# may be disposed in a number corresponding to the number of bits of the command/address signal C/A and the data DIO, respectively.

The memory controller 200 may include a host interface 210, a control engine 220, an error correction code (ECC) engine 230, a memory interface 240, a fault analysis engine 250, and a bus 260.

The host interface 210 may be an interface for communication between the host 20 and the memory controller 200. The host interface 210 may receive the request REQ from the host 20, receive the data DIO read from the memory device 100 through the memory interface 240, and transfer the received data DIO to the host 20.

The control engine 220 may receive the request REQ from the host 20 through the host interface 210. The control engine 220 may control each component of the memory controller 200 according to the request REQ. The control engine 220 may generate various commands (e.g., an active command, a precharge command, a read command, a write command, a repair command, etc.) and address, according to the request REQ. For example, the control engine 220 may generate an address to be activated together with an active command, and generate an address to be read or written together with a read command or a write command. The control engine 220 may generate an address to be repaired together with a repair command.

The control engine 220 may set the order of requests to be instructed to the memory device 100 among the requests REQs from the host 20 and generate a command to be applied to the memory device 100 according to the order of the predetermined operations. To improve the performance of the memory device 100, the control engine 220 may change the order in which the requests REQs are received from the host 20 and the order of the operations to be instructed to the memory device 100. For example, the control engine 220 may adjust the order so that a write operation is performed before a read operation, even if the host 20 requests the read operation of the memory device 100 first and the write operation later.

The ECC engine 230 may correct an error in the data DIO read from the memory device 100, and provide the corrected data to the host 20. When the number of error bits of the data DIO is out of the error correction capability of the ECC engine 230, the control engine 220 may notify the host 20 that an uncorrectable error UE has occurred.

The control engine 220 may generate a scrub command indicating a scrub operation for a predetermined number of times during a scrub period. For example, the control engine 220 may generate the scrub command for the number of times to check errors of all memory cells of the memory device 100 for a 24 hour period. The scrub operation may include a read operation for reading data from the memory device 100, an error check operation for checking and correcting an error in the read data, and a re-write operation for writing the error-corrected data back to the memory device 100. The control engine 220 may transmit the scrub command indicating a read operation and a re-write operation to the memory device 100, and the ECC engine 230 may perform an error check operation. The ECC engine 230 may generate an error information according to the error check operation.

The memory interface 240 may be configured to communicate with the memory device 100. The memory interface 240 may transmit the command/address signal C/A and the data DIO to the memory device 100, and receive the data DIO read from the memory device 100. For example, the memory interface 240 may provide the command/address signal C/A corresponding to a command and address generated by the control engine 220 to the memory device 100. In addition, the memory interface 240 may provide the data DIO corresponding to the request REQ provided from the host interface 210 to the memory device 100.

The fault analysis engine 250 may accumulate the error information generated by the ECC engine 230 during the error check operations. For example, the fault analysis engine 250 may generate error logging information by accumulating the error information during a preset monitoring section. The fault analysis engine 250 may analyze a fault of the memory device 100 by reflecting device information of the memory device 100 onto the accumulated error information (e.g., error logging information). The control engine 220 may notify the host 20 that an operation (Hereinafter, referred to as RAS operation) for improving reliability, accessibility, and serviceability (RAS) is required, based on a fault analysis result, or may indicate the RAS operation to the memory device 100. The RAS operation may include a post package repair operation, a page opening operation, a raw map operation, a host error correction operation, a bank spare/migration operation, and an operation of determining that the memory device is unusable. The fault analysis engine 250 may also be referred to as a fault analysis device and may be disposed outside the memory controller 200.

The memory cell array of the memory device 100 may be composed of a plurality of banks. Each bank may include a plurality of cell blocks arranged in an array form. The device information may include architectural information on a plurality of cell blocks included in each bank, and data input/output information. The fault analysis engine 250 may check error locations of data output from the plurality of cell blocks based on the accumulated error information, configure a physical layout of the plurality of cell blocks based on the architectural information to identify bad cell blocks including the error locations, and analyze faults of the bad cell blocks according to the data input/output information. The fault analysis engine 250 may store the device information regarding various devices in advance and extract a corresponding device information based on unique product information received from the memory device 100 during boot-up.

The memory controller 200 may transmit data between the host interface 210, the control engine 220, the ECC engine 230, the memory interface 240, and the fault analysis engine 250 through the bus 260. According to an embodiment, the host interface 210, the control engine 220, the ECC engine 230, the memory interface 240, and the fault analysis engine 250 may independently communicate with each other without using the bus 260. For example, the fault analysis engine 250 and the host interface 210 may communicate directly with each other without using the bus 260, and the host interface 210 and the memory interface 240 may also communicate directly with each other without using the bus 260.

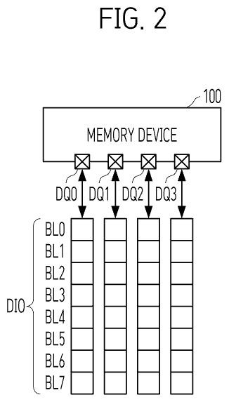

FIG. 2 is a diagram illustrating a data input/output operation of a memory device of FIG. 1.

Referring to FIG. 2, a memory device 100 may use a number of data pads (i.e., the first to fourth data pads DQ0 to DQ3) corresponding to a data bus width to input/output data DIO according to a preset data width option (e.g., 4-bit). In addition, the memory device 100 may perform a burst operation for converting data, outputted from the memory cell array in parallel, into a serial order and output the converted data during a preset burst length (e.g., 8).

Accordingly, the memory device 100 of FIG. 2 may input/output the data DIO of 4*8=32 bits in one read operation or write operation by inputting/output the data DIO through the first to fourth data pads DQ0 to DQ3 during a burst length BL0 to BL7.

The memory device 100 of FIG. 2 exemplarily illustrates a data width option set to 4 and a burst length is set to 8, and the proposed invention is not limited thereto. Various bit numbers of data may be input and output according to the setting of the data width option and the burst length.

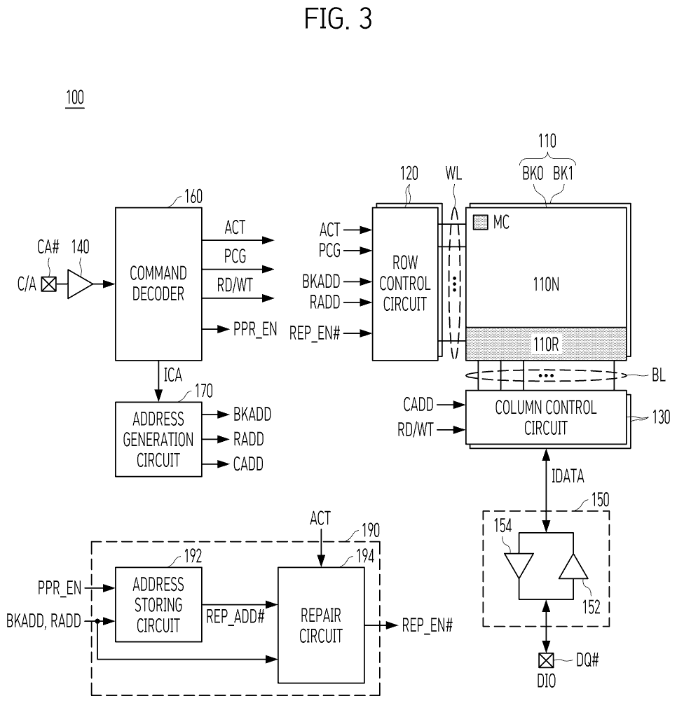

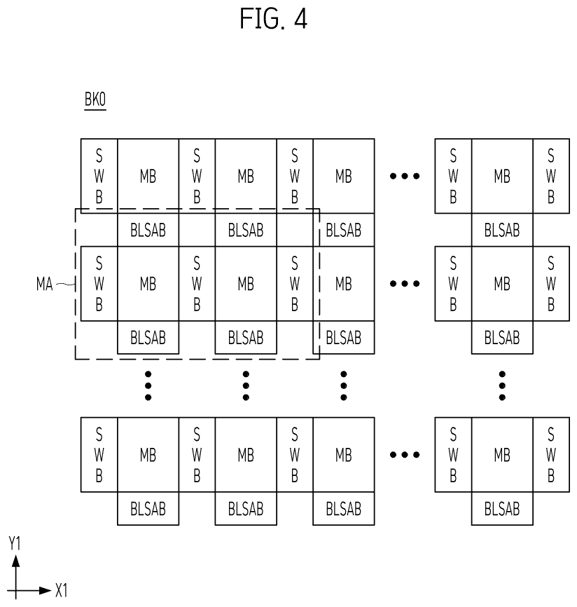

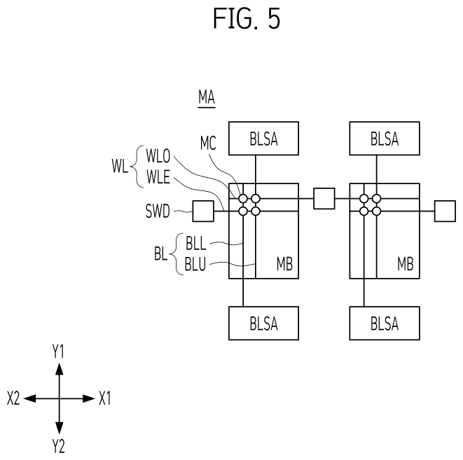

FIG. 3 is a block diagram illustrating a memory device of FIG. 1 according to an embodiment of the present invention. FIGS. 4 and 5 are diagrams illustrating a memory cell array for each bank in FIG. 3.

Referring to FIG. 3, a memory device 100 may include a memory cell array 110, a row control circuit 120, a column control circuit 130, a command/address (CA) receiving circuit 140, a data input/output circuit 150, a command decoder 160, an address generation circuit 170, and a repair control circuit 190.

The memory cell array 110 may be composed of a plurality of banks (for example, a first bank BK0 and a second bank BK1), each including a plurality of memory cells MC, respectively. The number of banks or the number of memory cells MC may be determined according to the capacity of the memory device 100. The row control circuit 120 and the column control circuit 130 may also be provided in a number corresponding to the number of the banks.

Each bank of the memory cell array 110 may be coupled to the row control circuit 120 through a plurality of word lines WL, and may be coupled to the column control circuit 130 through a plurality of bit lines BL. The plurality of word lines WL may extend in a first direction (e.g., a row direction) and may be sequentially arranged in a second direction (e.g., a column direction). The plurality of bit lines BL may extend in a column direction and may be sequentially arranged in a row direction.

Each bank of the memory cell array 110 may include a normal cell area 110N in which a plurality of normal word lines connected to normal memory cells are disposed, and a redundancy cell area 110R in which a plurality of redundancy word lines connected to redundancy memory cells are disposed. If a defective memory cell (i.e., a repair target cell) is found in the normal cell area 110N, a post package repair operation may be performed to replace a defective word line (i.e., a repair target word line) in which the defective cell is disposed, with a redundancy word line of the redundancy cell area 110R. In FIG. 3, only a configuration for a row repair operation is shown, but proposed embodiments are not limited thereto. According to other embodiments, a column repair operation may be supported by additionally arranging a redundancy cell area in which a plurality of redundancy bit lines for repairing defective bit lines are disposed.

Each bank of the memory cell array 110 may include a plurality of memory blocks (hereinafter, referred to as “cell blocks”), each including the plurality of memory cells MCs, respectively.

Referring to FIG. 4, the configuration of any one bank (e.g., the first bank BK0) of the memory cell array 110 is illustrated.

The first bank BK0 may include a plurality of cell blocks MB arranged in an array form in a first direction X1 and a second direction Y1 intersecting the first direction X1. Each cell block MB may include a plurality of memory cells MC connected between a plurality of word lines WL and a plurality of bit lines BL. In an embodiment of the present invention, the “cell block” may be defined as a set of memory cells that share the word lines WL and the bit lines BL and are arranged in the same form. Sub-word line driver regions SWB may be arranged between cell blocks MB in the first direction X1. A plurality of sub-word line drivers may be disposed in the sub-word line driver region SWB. Bit line sense amplifier regions BLSAB may be arranged between cell blocks MB in the second direction Y1. A plurality of bit line sense amplifiers may be disposed in the bit line sense amplifier region BLSAB.

For reference, in order to improve a propagation delay of a word line voltage that occurs as the number of memory cells connected to the word lines increases and a distance between the word lines decreases, one main word line may be divided into a plurality of (e.g., eight) sub-word lines, which are driven by the sub-word line drivers. Hereinafter, the word lines WL mentioned in the present invention may correspond to known sub-word lines, and the sub-word line drivers may be referred to as word line drivers.

Referring to FIG. 5, a partial area MA of FIG. 4 is shown.

Each of the cell blocks MB may include the memory cells MC connected between the word lines WL and the bit lines BL.

The squares between the cell blocks MB may represent the sub-word line drivers SWD, and the lines extending to the left and right of the sub-word line drivers SWD may represent the word lines. In reality, a much larger number of sub-word line drivers SWD and word lines exist, but only a part of the lines are shown to illustrate the simple structure.

Each of the cell blocks MB may include odd-numbered word lines (hereinafter, referred to as “first word lines WLO”) and even-numbered word lines (hereinafter, referred to as “second word lines WLE”) extending in the first direction X1 and alternating with each other in the second direction Y1. In odd-numbered cell blocks MB, the first word lines WLO may share sub-word line drivers SWD with an adjacent cell block in the first direction X1, and the second word lines WLE may share sub-word line drivers SWD with an adjacent cell block in a direction X2 opposite to the first direction X1. Conversely, in even-numbered cell blocks MB, the second word lines WLE may share sub-word line drivers SWD with an adjacent cell block in the first direction X1, and the first word lines WLO may share sub-word line drivers SWD with an adjacent cell block in the direction X2. That is, since two adjacent cell blocks MB in the first direction X1 share the sub-word line drivers SWD, one sub-word line driver SWD may be allocated to two adjacent cell blocks MB in the first direction X1.

Each of the cell blocks MB may include first bit lines BLU and second bit lines BLL extending in the second direction Y1 and alternately disposed in the first direction X1. The first bit lines BLU may share bit line sense amplifiers BLSA with an adjacent cell block (not illustrated) in the second direction Y1, and the second bit lines BLL may share bit line sense amplifiers BLSA with an adjacent cell block (not illustrated) in a direction Y2 opposite to the second direction Y1. That is, since two adjacent cell blocks MB in the second direction Y1 share the bit line sense amplifiers BLSA, one bit line sense amplifier BLSA may be allocated to two adjacent cell blocks MB in the second direction Y1.

Referring back to FIG. 3, the command/address receiving circuit 140 may receive a command/address signal C/A through command/address pads CA#. According to the type of the memory device 100, the command/address signal C/A may be input to the same input terminals, or the command/address signal C/A may be input to separate input terminals. In FIG. 3, it is illustrated that the command/address signal C/A is input to the same input terminals. The command/address signal C/A may be composed of multi-bits.

The data input/output circuit 150 may receive data DIO from a memory controller or transmit data DIO to the memory controller, through data pads DQ#. The data input/output circuit 150 may include a data input circuit 152 that receives data DIO to be written to the memory cell array 110 during a write operation, and a data output circuit 154 that transmits internal data IDATA read from the memory cell array 110 as data DIO during a read operation.

The command decoder 160 may decode the command/address signal C/A received by the command/address receiving circuit 140 to generate an active command ACT, a precharge command PCG, a write command WT, a read command RD, a repair command PPR_EN, and the like. The active command ACT is a signal input when an active operation is instructed, the precharge command PCG is a signal input when a precharge operation is instructed, the write command WT is a signal input when a write operation is instructed, and the read command RD may be a signal input when a read operation is instructed. For reference, when an error check operation is instructed, a read command RD indicating a read operation and a write command WT for a re-write operation may be sequentially input together with an address. The repair command PPR_EN may be a signal input when a post package repair operation is instructed.

The address generation circuit 170 may classify an internal address ICA received from the command decoder 160 into a bank address BKADD, a row address RADD, and a column address CADD. According to an embodiment, the address generation circuit 170 may classify some bits of the internal address ICA into a bank address BKADD and a row address RADD, and classify the remaining bits into a column address CADD. Alternatively, the address generation circuit 170 may classify the address into a bank address BKADD and a row address RADD when an active operation is instructed as a result of decoding the command decoder 160, and classify the address as a column address CADD when a read and write operation is instructed.

For reference, the bank address BKADD may be an address for selecting one bank among the plurality of banks BK0 and BK1. The row address RADD is an address for selecting one word line among the plurality of word lines WL, and the plurality of word lines WL may correspond to a plurality of rows, respectively. The column address CADD is an address for selecting a predetermined number of bit lines BL among the plurality of bit lines BL, and one column may correspond to a predetermined number of bit lines BL selected by the column address CADD. The bank address BKADD and the row address RADD may be provided to the row control circuit 120, and the column address CADD may be provided to the column control circuit 130.

The row control circuit 120 may perform an active operation of activating a word line selected by the row address RADD of the bank corresponding to the bank address BKADD in response to the active command ACT, and may perform a precharge operation of precharging the activated word line in response to the precharge command PCG. In addition, when any one of a plurality of repair control signals REP_EN# is activated during the active operation, regardless of the bank address BKADD and the row address RADD, a redundancy address corresponding to the activated repair control signal may be mapped, and a redundancy word line corresponding to the redundancy address may be activated. For reference, when 10 redundancy word lines are arranged in the redundancy cell area 110R of each bank, the repair control signals REP_EN# are allocated as the number of banks*10 (e.g., 20), and each repair control signal may correspond to a redundancy address for designating a certain redundancy row of any bank. For example, the 19-th repair control signal REP_EN19 may be activated to designate the 9-th redundancy row of the second bank BK1.

The column control circuit 130 may select some bit lines of the bit lines BL of the memory cell array 110 according to the column address CADD, perform a read operation of reading the internal data IDATA from the memory cells MC through the selected bit lines in response to the read command RD, or perform a write operation of writing the internal data IDATA to the memory cells MC through the selected bit lines in response to the write command WT.

The repair control circuit 190 may store the bank address BKADD and the row address RADD as one of a plurality of repair addresses REP_ADD# according to the repair command PPR_EN. The repair control circuit 190 may selectively activate the plurality of repair signals REP_EN# by comparing the bank address BKADD and the row address RADD with the stored repair addresses REP_ADD#, respectively, when the active command ACT is input.

For example, the repair control circuit 190 may include an address storing circuit 192 and a repair circuit 194.

The address storing circuit 192 may include a plurality of unit memories for storing the plurality of repair addresses REP_ADD#, respectively. The unit memories may be composed of an anti-fuse, an array e-fuse (ARE) circuit, a NAND flash memory, a NOR flash memory, an EPROM, an EEPROM, or a volatile memory such as DRAM or flip-flop. The address storing circuit 192 may sequentially store the bank address BKADD and the row address RADD in the unit memories as the plurality of repair addresses REP_ADD#, according to the repair command PPR_EN.

The repair circuit 194 may generate the repair signals REP_EN# by comparing the bank address BKADD and the row address RADD with the stored repair addresses REP_ADD# according to the active command ACT, while activating a repair control signal corresponding to a repair address in which the comparison result matches.

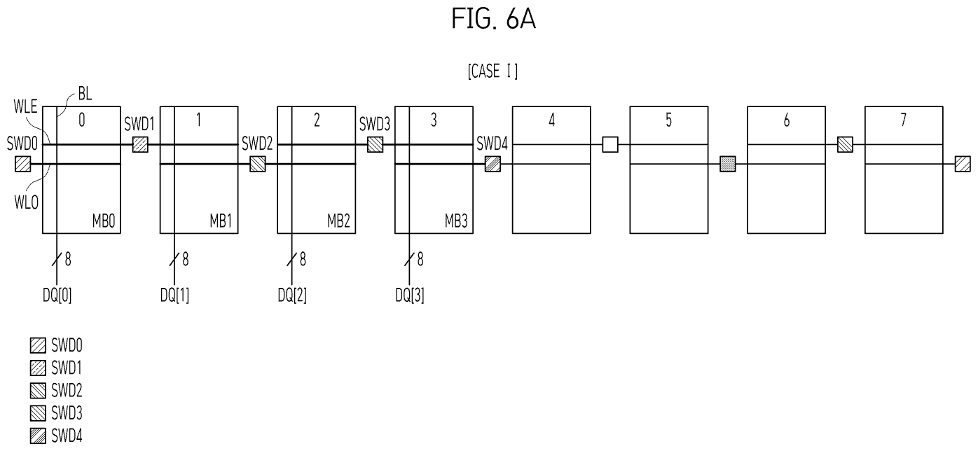

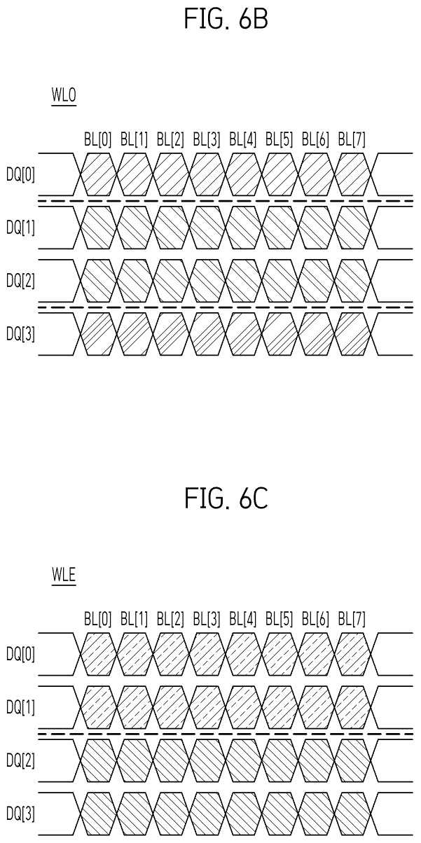

As described above, the fault analysis engine 250 of the memory controller 200 of FIG. 1 may analyze the fault of the memory device 100 by reflecting the device information of the memory device 100 onto the accumulated error information. In this case, the device information may include the architectural information on the plurality of cell blocks included in each bank, and the data input/output information. The architectural information on the plurality of cell blocks may include one or more selected from a layout of word lines and bit lines of each cell block, a layout of redundancy word lines and bit lines of each cell block, the number of memory cells arranged per word line, the number of bit lines specified by one column address, a layout of bit line sense amplifiers of each cell block, and a layout of word line drivers (or sub-word line drivers) of each cell block, as shown in FIGS. 4 and 5. Also, the data input/output information may include a mapping information between the plurality of data pads and the plurality of cell blocks according to the data width option and the burst length, as described in FIG. 2. The mapping information may include one or more selected from a data pad (DQ) aligned structure, a burst length (BL) aligned structure, and a mixed aligned structure of the DQ aligned structure and the BL aligned structure, which will be described in FIGS. 6A to 6C.

Hereinafter, a data input/output operation according to a mapping information of the memory device 100 will be described with reference to FIGS. 6A to 8C. In the following exemplary embodiments, the data width option is set to 4 and the burst length is set to 8.

FIGS. 6A to 6C are diagrams for describing a data input/output operation in a first input/output mode (CASE I).

Referring to FIG. 6A, in the first input/output mode (CASE I), each of first to fourth cell blocks MB0 to MB3 may correspond to first to fourth data pads DQ[0] to DQ[3] on a one-to-one basis, and data of one cell block may be input/output through a corresponding data pad during burst length BL[0] to BL[7]. The first input/output mode (CASE I) may be referred to as a DQ aligned structure. In FIG. 6A, a case in which 8-bit data is output per cell block is illustrated.

Referring to FIG. 6B, when an odd-numbered word line WLO is selected, odd-numbered sub-word line drivers SWD0, SWD2, and SWD4 may be activated. 8-bit data of the first cell block MB0 may be input and output through the first data pad DQ[0] by a first sub-word line driver SWD0, during the burst length BL[0] to BL[7]. 8-bit data of each of the second cell block MB1 and the third cell block MB2 may be input and output through each of the second data pad DQ[1] and the third data pad DQ[2] by a third sub-word line driver SWD2, during the burst length BL[0] to BL[7]. 8-bit data of the fourth cell block MB3 may be input and output through the fourth data pad DQ[3] by a fifth sub-word line driver SWD4, during the burst length BL[0] to BL[7].

On the other hand, referring to FIG. 6C, when an even-numbered word line WLE is selected, even-numbered sub-word line drivers SWD1 and SWD3 may be activated. 8-bit data of each of the first cell block MB0 and the second cell block MB1 may be input and output through each of the first data pad DQ[0] and the second data pad DQ[1] by a second sub-word line driver SWD1, during the burst length BL[0] to BL[7]. 8-bit data of each of the third cell block MB2 and the fourth cell block MB3 may be input and output through each of the third data pad DQ[2] and the fourth data pad DQ[3] by a fourth sub-word line driver SWD3, during the burst length BL[0] to BL[7].

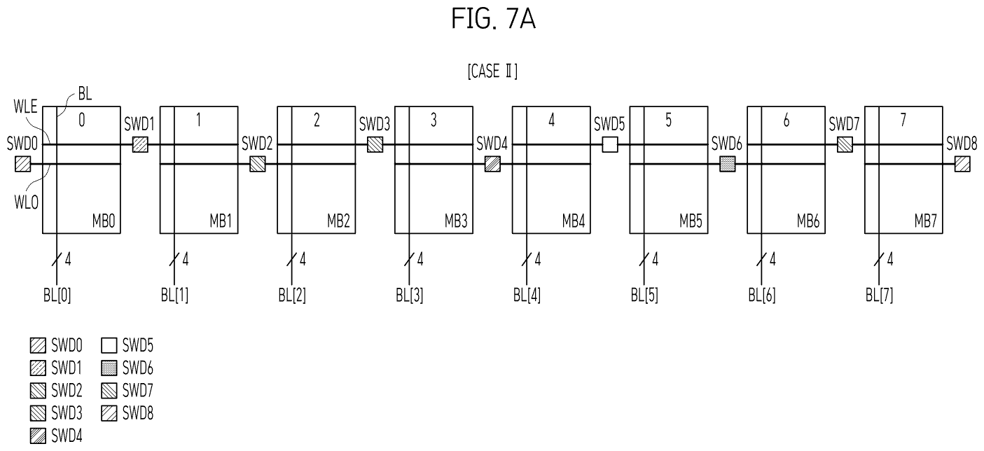

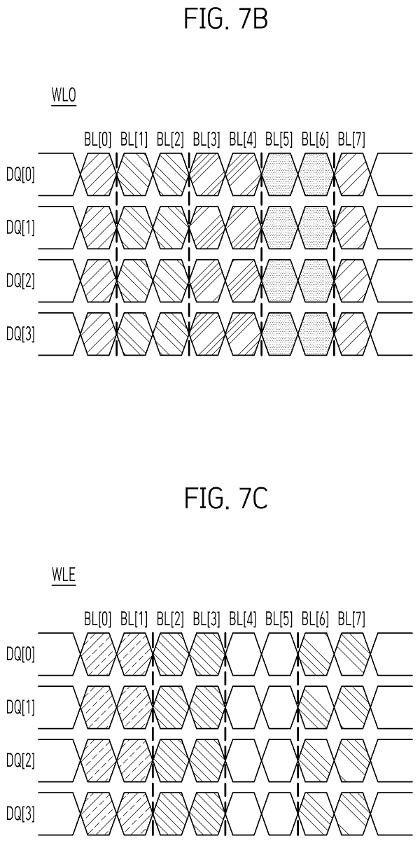

FIGS. 7A to 7C are diagrams for describing a data input/output operation in a second input/output mode (CASE II).

Referring to FIG. 7A, in the second input/output mode (CASE II), each of first to eighth cell blocks MB0 to MB7 may correspond to unit bursts of the burst length BL[0] to BL[7] on a one-to-one basis, and data of one cell block may be input/output through all data pads DQ[0] to DQ[3] during a corresponding unit burst of the burst length BL[0] to BL[7]. The second input/output mode (CASE II) may be referred to as a first BL aligned structure. In FIG. 7A, a case in which 4-bit data is output per cell block is illustrated.

Referring to FIG. 7B, when an odd-numbered word line WLO is selected, odd-numbered sub-word line drivers SWD0, SWD2, SWD4, SWD6, and SWD8 may be activated. 4-bit data of the first cell block MB0 may be input and output through all data pads DQ[0] to DQ[3] by a first sub-word line driver SWD0, during a first unit burst BL[0]. 4-bit data of each of the second cell block MB1 and the third cell block MB2 may be input and output through all data pads DQ[0] to DQ[3] by a third sub-word line driver SWD2, during second and third bursts BL[1] and BL[2], respectively. In this way, 4-bit data of the eighth cell block MB7 may be input and output through all data pads DQ[0] to DQ[3] by a ninth sub-word line driver SWD8, during an eighth unit burst BL[7].

Referring to FIG. 7C, when an even-numbered word line WLE is selected, even-numbered sub-word line drivers SWD1, SWD3, SWD5, and SWD7 may be activated. 4-bit data of each of the first cell block MBO and the second cell block MB1 may be input and output through all data pads DQ[0] to DQ[3] by a second sub-word line driver SWD1, during first and second unit bursts BL[0] and BL[1], respectively. In this way, 4-bit data of each of the seventh cell block MB6 and the eighth cell block MB7 may be input and output through all data pads DQ[0] to DQ[3] by an eighth sub-word line driver SWD7, during seventh and eighth unit bursts BL[6] and BL[7].

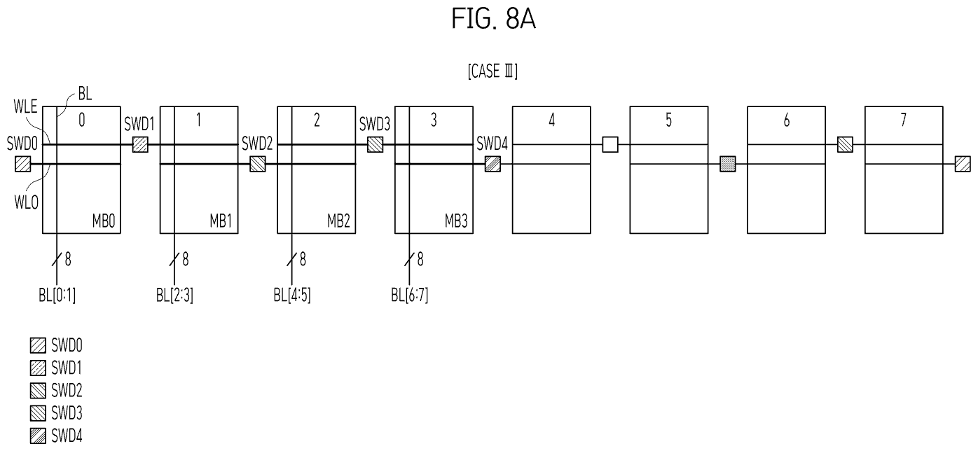

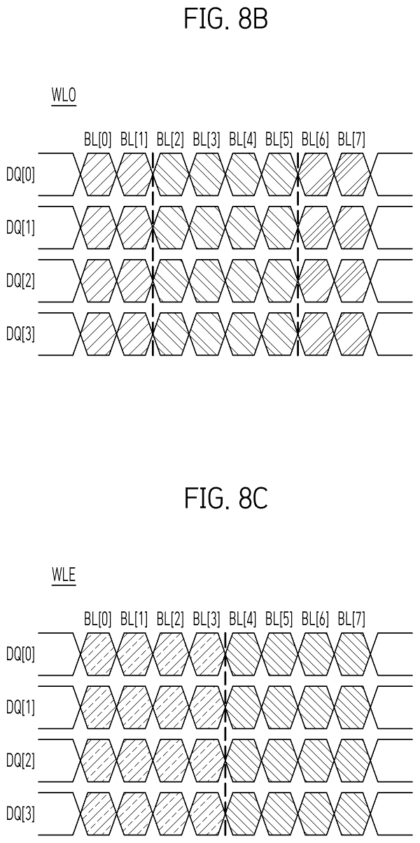

FIGS. 8A to 8C are diagrams illustrating data input/output operations in a third input/output mode (CASE III).

Referring to FIG. 8A, in the third input/output mode (CASE III), each of first to fourth cell blocks MB0 to MB3 may correspond to two unit bursts of burst length BL[0] to BL[7] on a one-to-one basis, and data of one cell block may be input/output through all data pads DQ[0] to DQ[3] during two corresponding unit bursts. The third input/output mode (CASE III) may be referred to as a second BL aligned structure. In FIG. 8A, a case in which 8-bit data is output per cell block is illustrated.

Referring to FIG. 8B, when an odd-numbered word line WLO is selected, odd-numbered sub-word line drivers SWD0, SWD2, and SWD4 may be activated. 8-bit data of the first cell block MB0 may be input and output through all data pads DQ[0] to DQ[3] by a first sub-word line driver SWD0, during first and second unit burst BL[0:1]. 8-bit data of each of the second cell block MB1 and the third cell block MB2 may be input and output through all data pads DQ[0] to DQ[3] by a third sub-word line driver SWD2, during third through sixth bursts BL[2:5]. 8-bit data of the fourth cell block MB3 may be input and output through all data pads DQ[0] to DQ[3] by a fifth sub-word line driver SWD4, during seventh and eighth unit burst BL[6:7].

Referring to FIG. 8C, when an even-numbered word line WLE is selected, even-numbered sub-word line drivers SWD1 and SWD3 may be activated. 8-bit data of each of the first cell block MB0 and the second cell block MB1 may be input and output through all data pads DQ[0] to DQ[3] by a second sub-word line driver SWD1, during first through fourth unit bursts BL[0:3]. 8-bit data of each of the third cell block MB2 and the fourth cell block MB3 may be input and output through all data pads DQ[0] to DQ[3] by a fourth sub-word line driver SWD3, during fifth through eighth unit bursts BL[4:7].

Although not shown in FIGS. 6A to 8C, the data input/output operation may be performed according to a mixed input/output mode in which at least two of the first input/output mode (CASE I), the second input/output mode (CASE II), and the third input/output mode (CASE III) are mixed. In the mixed input/output mode, some cell blocks among a plurality of cell blocks may correspond to data pads, and the remaining cell blocks may correspond to some unit bursts of the burst length, thereby performing the data input/output operation.

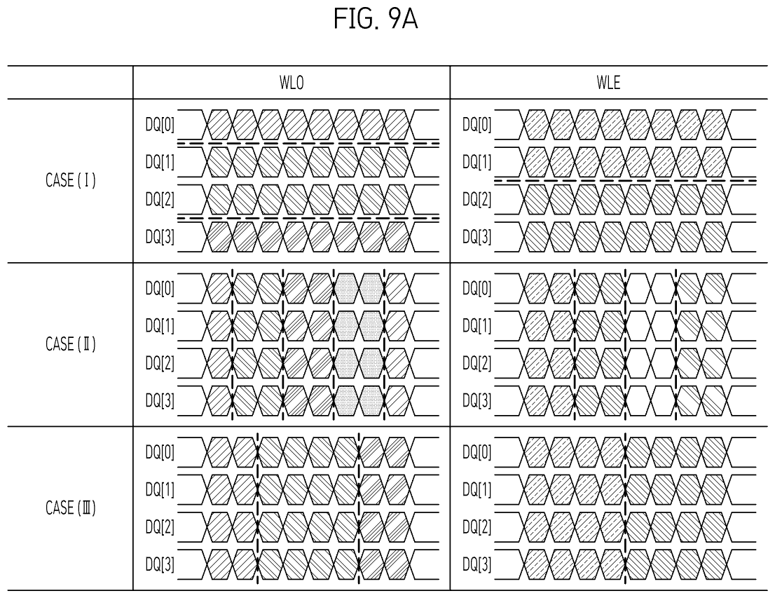

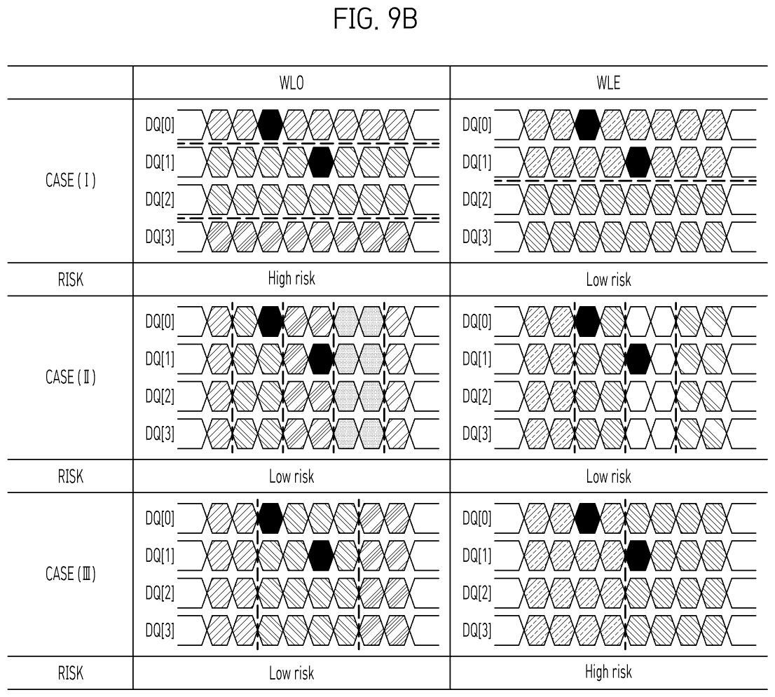

Hereinafter, a method of analyzing a fault of a memory device by reflecting an architecture information on a plurality of cell blocks and data input/output information onto an accumulated error information will be schematically described with reference to FIGS. 9A and 9B.

FIGS. 9A and 9B are diagrams for describing a fault analysis method according to an error location in first to third input/output modes.

Referring to FIG. 9A, a data input/output operation performed for each of first to third input/output modes is illustrated. A dotted line illustrated in FIG. 9A represents a fault boundary of one sub-word line driver described in FIGS. 6A to 8C.

Referring to FIG. 9B, a black hatched box represents an error occurring in each of the data of the first data pad DQ[0] during the third unit burst BL[2] and the data of the second data pad DQ[1] during the fifth unit burst BL[4]. In FIGS. 9A to 9C, it is assumed that the host has error correction capability capable of correcting errors in consecutive 16-bit data.

In the first input/output mode (CASE I), when the odd word line WLO is selected, it is determined that there is a fault of the first sub-word line driver SWD0 and/or a fault of the third sub-word line driver SWD2. When a fault occurs in two sub-word line drivers, it is beyond the error correction capability of the host, and thus may be determined as a high risk. On the other hand, when the even-numbered word line WLE is selected, it is determined that there is a fault of the second sub-word line driver SWD1. In this case, when a fault occurs in one sub-word line driver, it may be included in the error correction capability of the host and may be determined as a low risk.

In the second input/output mode (CASE II), when the odd word line WLO is selected, it is determined that there is a fault of the third sub-word line driver SWD2 and/or a fault of the fifth sub-word line driver SWD4. In this case, when two errors are included in consecutive 16-bit data, it is included in the error correction capability of the host, and thus it may be determined as a low risk. When the even-numbered word line WLE is selected, it is determined that there is a fault of the fourth sub-word line driver SWD3 and/or a fault of the sixth sub-word line driver SWD5. In this case, when two errors are included in consecutive 16-bit data, it may be determined as a low risk.

In the third input/output mode (CASE III), when the odd-numbered word line WLO is selected, it is determined that there is a fault of the third sub-word line driver SWD2 and may be determined as a low risk. On the contrary, when the even-numbered word line WLE is selected, it is determined that there is a fault of the second sub-word line driver SWD1 and/or a fault of the fourth sub-word line driver SWD3. When a fault occurs in two sub-word line drivers, it is beyond the error correction capability of the host, and thus may be determined as a high risk.

As described above, even if an error occurs at the same location, the fault analysis may be different depending on the layout information (i.e., architectural information of cell blocks) and data input/output information (i.e., a mapping information) of the selected word line. In the present invention, it is possible to improve the prediction rate of occurrences of UEs by analyzing faults based on actual architecture by reflecting architectural information and data input/output information onto accumulated error information.

Hereinafter, a detailed configuration and operation for fault analysis according to embodiments of the present invention will be described.

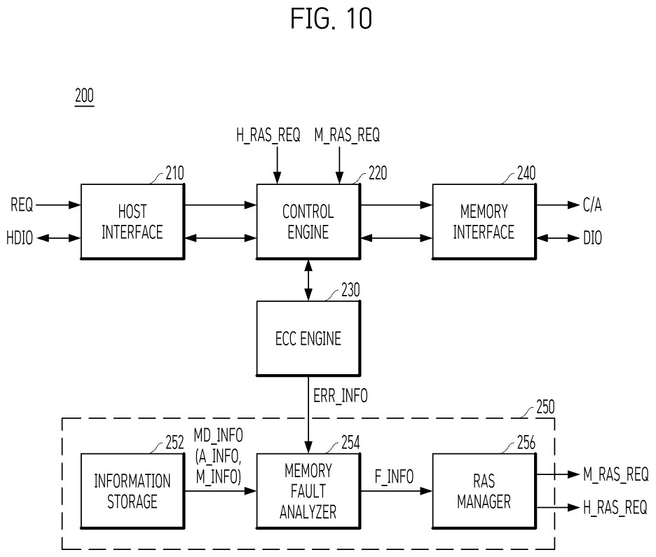

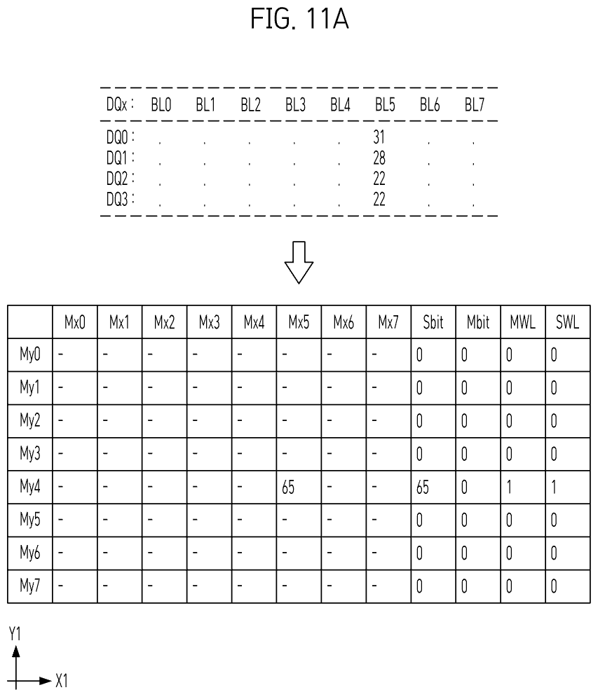

FIG. 10 is a detailed block diagram illustrating a memory controller of FIG. 1 according to an embodiment of the present invention.

Referring to FIG. 10, a host interface 210 may receive a request REQ from a host (20 of FIG. 1) and transmit and receive host data HDIO.

A memory interface 240 may transmit the command/address signal C/A to a memory device (100 of FIG. 1) and transmit and receive data DIO.

A control engine 220 may control operations of the host interface 210, an ECC engine 230, the memory interface 240, and a fault analysis engine 250. The control engine 220 may generate a command and an address corresponding to the request REQ, and generate a command and an address required internally. The control engine 220 may schedule and transmit a command, an address, and data between the host interface 210 and the memory interface 240.

The ECC engine 230 may correct an error in data DIO read from the memory device and provide the corrected data to the host.

The control engine 220 may transmit a scrub command and an address for a scrub operation to the memory device, and the ECC engine 230 may generate error information ERR_INFO by performing an error check operation on the data DIO read from the memory device.

The fault analysis engine 250 may analyze the fault of the memory device by accumulating the error information ERR_INFO during a monitoring section and reflecting device information MD_INFO including architectural information A_INFO of a plurality of cell blocks of the memory device and data input/output information M_INFO, onto the accumulated error information ERR_INFO.

More specifically, the fault analysis engine 250 may include an information storage 252, a memory fault analyzer 254, and a reliability, accessibility, and serviceability (RAS) manager 256.

The information storage 252 may store the architectural information A_INFO and the data input/output information M_INFO. The information storage 252 may store the device information for various devices. For example, the information storage 252 may store the device information in advance during a manufacturing process. The information storage 252 may receive unique product information from the memory device 100 for each boot-up and extract a corresponding device information MD_INFO based on the unique product information. For example, the information storage 252 may receive unique product information stored in a mode register of the memory device using a mode setting command and extract at least one of the architectural information A_INFO and the data input/output information M_INFO based on the unique product information.

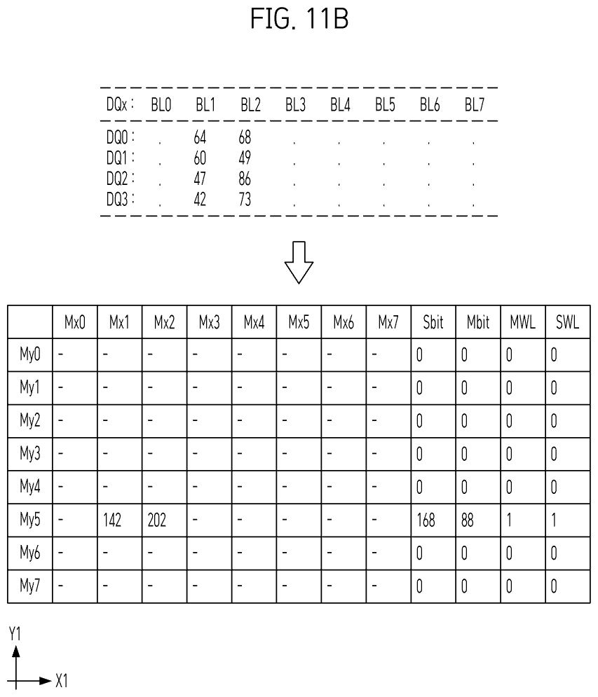

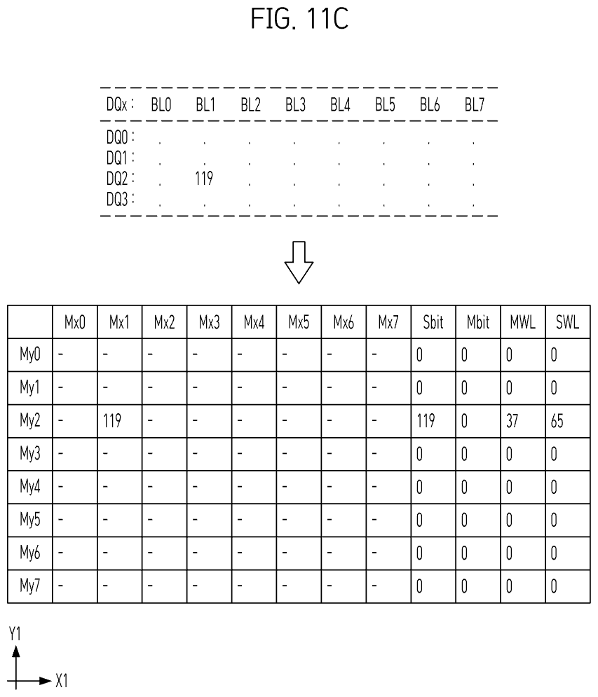

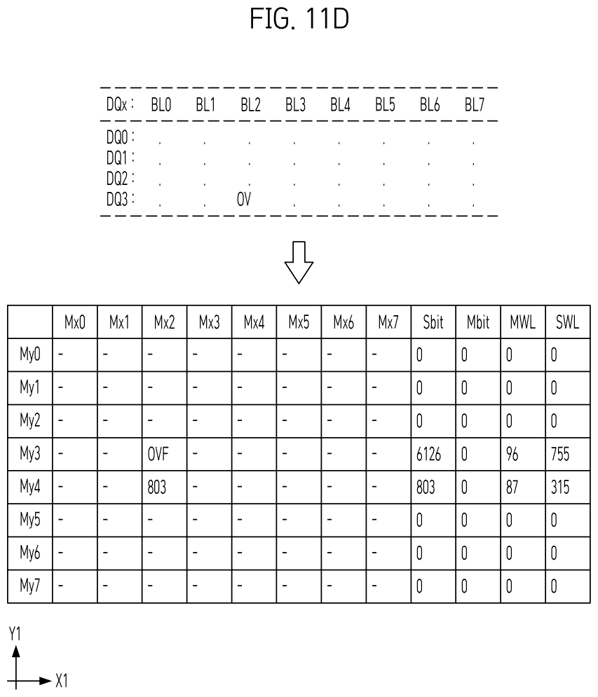

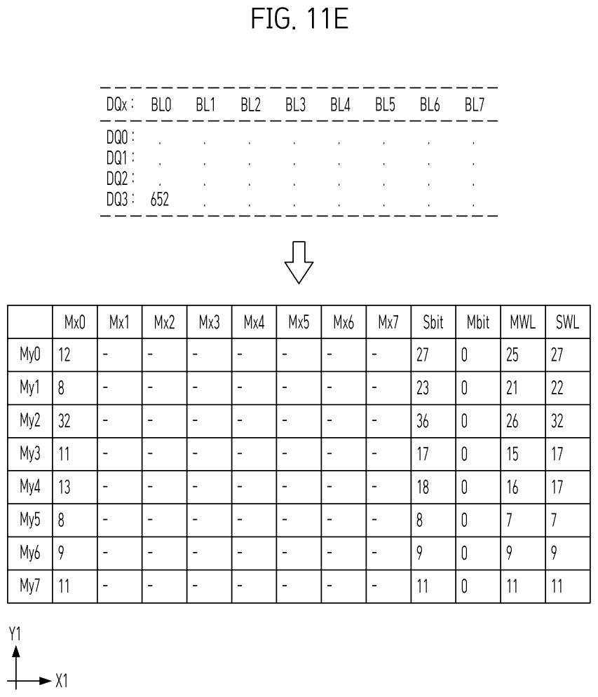

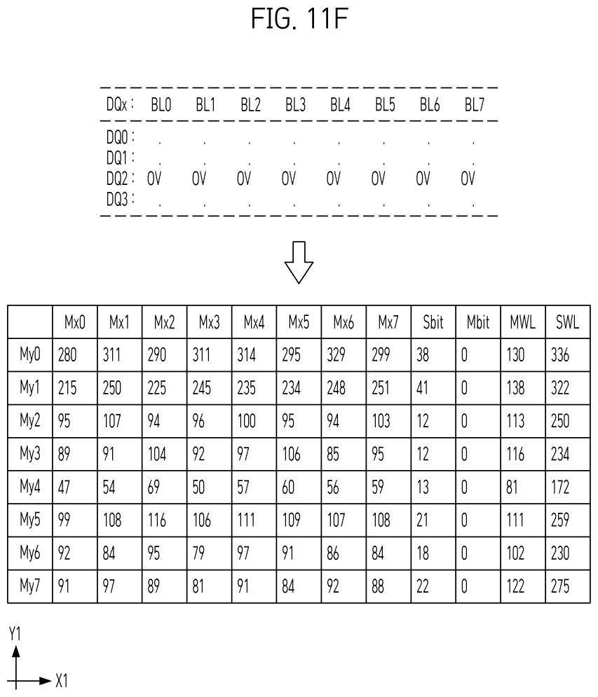

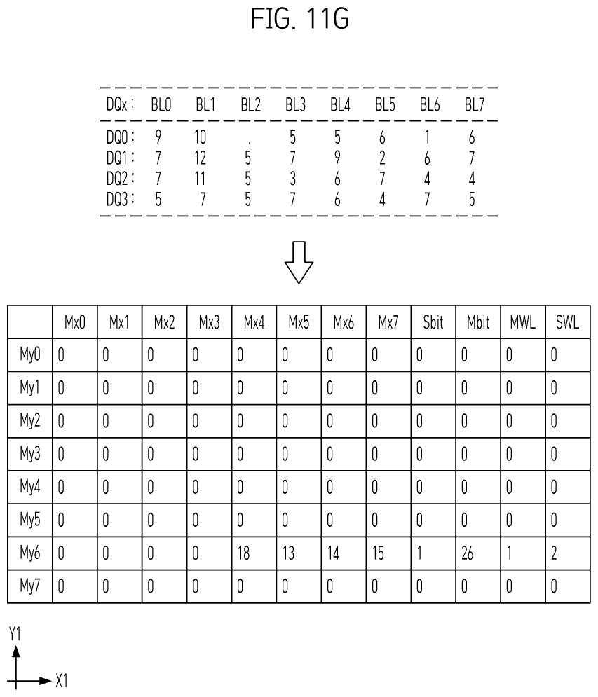

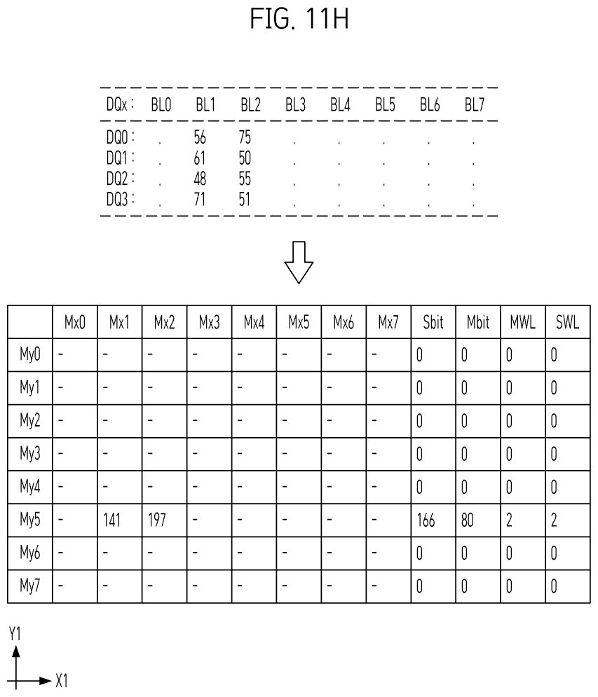

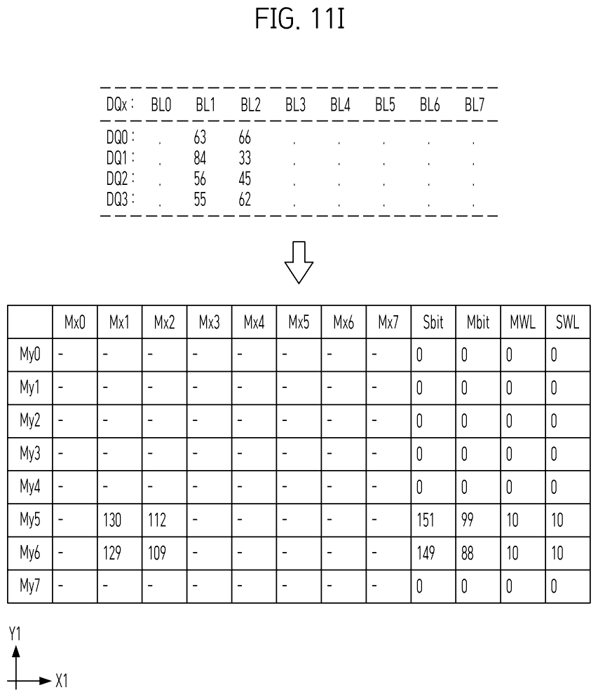

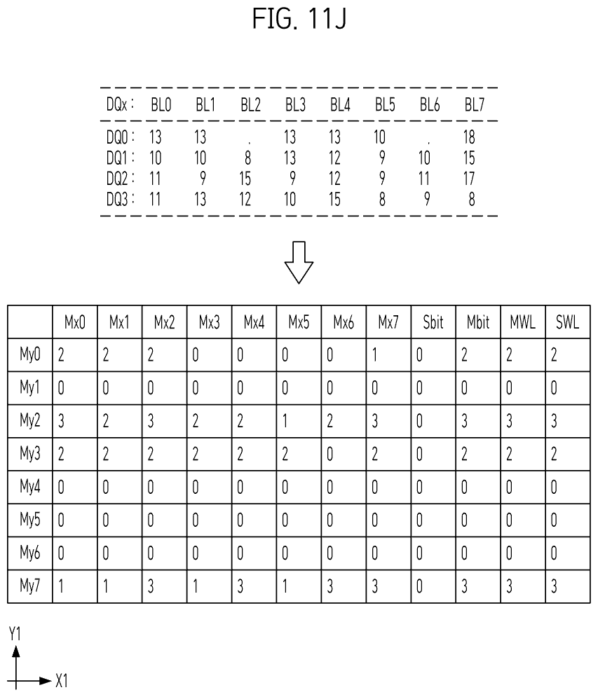

The memory fault analyzer 254 may accumulate and collect the error information ERR_INFO generated by the ECC engine 230 during the monitoring section, and check error locations of data output from a plurality of cell blocks based on the accumulated error information ERR_INFO. The memory fault analyzer 254 may configure a physical layout of the plurality of cell blocks based on the architectural information A_INFO. That is, the memory fault analyzer 254 may configure the actual physical layout of the cell blocks based on a layout of word lines and bit lines of each cell block, a layout of redundancy word lines and bit lines of each cell block, the number of memory cells arranged per word line, the number of bit lines specified by one column address, a layout of bit line sense amplifiers of each cell block, and a layout of word line drivers of each cell block, included in the architectural information A_INFO. Also, the memory fault analyzer 254 may identify defective cell blocks including the error locations from the physical layout to generate a fault information F_INFO related to the defective cell blocks according to the data input/output information M_INFO. Detailed operations of the memory fault analyzer 254 will be exemplarily described with reference to FIGS. 11A to 11J.

The RAS manager 256 may request the control engine 220 to perform a RAS operation that improves the reliability of the memory device, based on the fault information F_INFO. For example, the RAS manager 256 may transmit a first operation request M_RAS_REQ for instructing a RAS operation to a memory device, or a second operation request H_RAS_REQ for requesting a RAS operation to a host.

The control engine 220 may instruct the memory device to perform a post package repair operation in response to the first operation request M_RAS_REQ. The control engine 220 may request an error correction operation, a page offlining operation, a row remap operation, a bank sparing/migration operation, or an unuse of the memory device to the host in response to the second operation request H_RAS_REQ.

FIGS. 11A to 11J are diagrams for illustrating operations of a memory fault analyzer according to embodiments of the present disclosure. In the following exemplary embodiment, data input/output information M_INFO set to the second input/output mode (CASE II) will be described.

Referring to FIG. 11A, a memory fault analyzer 254 may accumulate error information ERR_INFO during the monitoring section to check errors that have occurred in data of all data pads DQ0 to DQ3 during a sixth unit burst BL5 (see the upper table of FIG. 11A). The memory fault analyzer 254 may configure cell blocks Mx0 to Mx7 arranged in a first direction X1 (i.e., a row direction) and cell blocks My0 to My7 arranged in a second direction Y1 (i.e., a column direction) according to the architectural information A_INFO, and may configure an actual physical layout of the cell blocks based on a layout of word lines and bit lines of each cell block, a layout of redundancy word lines and bit lines of each cell block, the number of memory cells arranged per word line, the number of bit lines specified by one column address, a layout of bit line sense amplifiers of each cell block, and a layout of word line drivers of each cell block.

In addition, the memory fault analyzer 254 may verify that a single-bit error Sbit has occurred only in a specific word line SWL of the defective cell block arranged in (Mx5, My4) from the physical layout, and generate fault information F_INFO related to the defective cell block based on the data input/output information M_INFO (see the lower table of FIG. 11A). The memory fault analyzer 254 may generate the fault information F_INFO indicating that a fault has occurred only on one side of a word line (i.e., sub-word line) or sub-word line driver (SWD4 or SWD5 of FIG. 7A) connected to the defective cell block.

Referring to FIG. 11B, the memory fault analyzer 254 may accumulate the error information ERR_INFO during the monitoring section to check errors that have occurred in data of all the data pads DQ0 to DQ3 during a second unit burst BL1 and a third unit burst BL2 (see the upper table of FIG. 11B). The memory fault analyzer 254 may verify that both a single-bit error Sbit and a multi-bit error Mbit have occurred only in a specific word line SWL of the defective cell blocks arranged in (Mx1, My5) and (Mx2, My5) adjacent to each other in the row direction X1 from the actual physical layout of the plurality of cell blocks configured according to the architectural information A_INFO, and generate the fault information F_INFO based on the data input/output information M_INFO (see the lower table of FIG. 11B). The memory fault analyzer 254 may generate the fault information F_INFO indicating that a fault has occurred on both sides of the sub-word line driver (SWD2 of FIG. 7A) shared by the defective cell blocks.

Referring to FIG. 11C, the memory fault analyzer 254 may accumulate the error information ERR_INFO during the monitoring section to check errors that have occurred in data of the third data pad DQ2 during the second unit burst BL1 (see the upper table of FIG. 11C). The memory fault analyzer 254 may verify that many single-bit errors Sbit have occurred in the word lines of the defective cell block arranged in (Mx1, My2) from the actual physical layout of the plurality of cell blocks configured according to the architectural information A_INFO, and generate the fault information F_INFO based on the data input/output information M_INFO (see the lower table of FIG. 11C). The memory fault analyzer 254 may generate the fault information F_INFO indicating that a fault has occurred in a specific bit line of the defective cell block.

Referring to FIG. 11D, the memory fault analyzer 254 may accumulate the error information ERR_INFO during the monitoring section to check an overflow OV of errors that have occurred in data of the fourth data pad DQ3 during the third unit burst BL2 (see the upper table of FIG. 11D). The memory fault analyzer 254 may verify that many single-bit errors Sbit have occurred in the word lines of defective cell blocks arranged in (Mx2, My3) and (Mx2, My4) adjacent to each other in the column direction Y1 from the actual physical layout of the plurality of cell blocks configured according to the architectural information A_INFO, and generate the fault information F_INFO based on the data input/output information M_INFO (see the lower table of FIG. 11D). The memory fault analyzer 254 may generate the fault information F_INFO indicating that a fault has occurred in a bit line sense amplifier connected to a bit line of adjacent upper and lower defective cell blocks in the column direction Y1.

Referring to FIG. 11E, the memory fault analyzer 254 may accumulate the error information ERR_INFO during the monitoring section to check errors that have occurred in data of the fourth data pad DQ3 during the first unit burst BL0 (see the upper table of FIG. 11E). The memory fault analyzer 254 may verify that single-bit errors Sbit have occurred in the word lines of defective cell blocks arranged in (Mx0, My0 to My7) in the column direction Y1 from the actual physical layout of the plurality of cell blocks configured according to the architectural information A_INFO, and generate the fault information F_INFO based on the data input/output information M_INFO (see the lower table of FIG. 11E). The memory fault analyzer 254 may generate the fault information F_INFO indicating that a fault has occurred in a data path of cell blocks arranged in the column direction Y1.

Referring to FIG. 11F, the memory fault analyzer 254 may accumulate the error information ERR_INFO during the monitoring section to check an overflow OV of errors that have occurred in data of the third data pad DQ2 during the burst length BL0 to BL7 (see the upper table of FIG. 11F). The memory fault analyzer 254 may verify that single-bit errors Sbit have occurred, from the actual physical layout of the plurality of cell blocks configured according to the architectural information A_INFO, and generate the fault information F_INFO based on the data input/output information M_INFO (see the lower table of FIG. 11F). In this case, the memory fault analyzer 254 may generate the fault information F_INFO indicating that a fault has occurred in a specific data pad (i.e., DQ2) by referring to error information of the remaining banks.

Referring to FIG. 11G, the memory fault analyzer 254 may accumulate the error information ERR_INFO during the monitoring section to check errors that have occurred in data of all data pads DQ0 to DQ3 during the burst length BL0 to BL7 (see the upper table of FIG. 11G). The memory fault analyzer 254 may verify that both single-bit errors Sbit and multi-bit errors and Mbit have occurred in the word lines SWL included in a specific main word line MWL of the defective cell blocks from the actual physical layout of the plurality of cell blocks configured according to the architectural information A_INFO, and generate the fault information F_INFO according to the data input/output information M_INFO (refer to the lower table of FIG. 11G). In this case, the memory fault analyzer 254 may generate the fault information F_INFO indicating that a fault has occurred in the specific main word line MWL.

Referring to FIG. 11H, the memory fault analyzer 254 may accumulate the error information ERR_INFO during the monitoring section to check errors that have occurred in data of all data pads DQ0 to DQ3 during the second unit burst BL1 and the third unit burst BL2 (see the upper table of FIG. 11H). The memory fault analyzer 254 may verify that single-bit errors Sbit and multi-bit errors Mbit have occurred in two main word lines MWL shared by defective cell blocks arranged in (Mx1, My5) and (Mx2, My5) adjacent to each other in the row direction X1 from the actual physical layout of the plurality of cell blocks configured according to the architectural information A_INFO, and generate the fault information F_INFO based on the data input/output information M_INFO (see the lower table of FIG. 11H). In this case, when two main word lines MWL are adjacent to each other, and the single-bit errors Sbit and the multi-bit errors Mbit occur only in the same order of sub-word lines among eight sub-word lines connected to each of two adjacent main word lines MWL, the memory fault analyzer 254 may generate the fault information F_INFO indicating a fault in a contact shared by sub-word line drivers for driving the same order of sub-word lines according to two adjacent main word lines MWL.

Referring to FIG. 11I, the memory fault analyzer 254 may accumulate the error information ERR_INFO during the monitoring section to check errors that have occurred in data of all data pads DQ0 to DQ3 during the second unit burst BL1 and the third unit burst BL2 (see the upper table of FIG. 11I). The memory fault analyzer 254 may verify that single-bit errors Sbit and multi-bit errors Mbit have occurred in the main word line MWL shared by the defective cell blocks arranged in (Mx1, My5) and (Mx2, My5) adjacent to each other in the row direction X1, and in the main word line MWL shared by the defective cell blocks arranged in (Mx1, My6) and (Mx2, My6) adjacent to each other in the row direction X1, from the actual physical layout of the plurality of cell blocks configured according to the architectural information A_INFO, and generate the fault information F_INFO based on the data input/output information M_INFO (see the lower table of FIG. 11I). In this case, when the single-bit errors Sbit and the multi-bit errors Mbit occur only in the same order of sub-word lines among eight sub-word lines connected to each of a plurality of main word lines (e.g., 10), the memory fault analyzer 254 may generate the fault information F_INFO indicating a fault in a signal path commonly provided to sub-word line drivers for driving the same order of sub-word lines according to the plurality of main word lines MWL.

Referring to FIG. 11J, the memory fault analyzer 254 may accumulate the error information ERR_INFO during the monitoring section to check errors that have occurred in data of all data pads DQ0 to DQ3 during the burst length BL0 to BL7 (see the upper table of FIG. 11J). The memory fault analyzer 254 may verify that sporadic errors have occurred in a plurality of cell blocks from the actual physical layout of the plurality of cell blocks configured according to the architectural information A_INFO, and generate the fault information F_INFO based on the data input/output information M_INFO (see the lower table of FIG. 11J). In this case, the memory fault analyzer 254 may generate the fault information F_INFO indicating that a number of unknown (or miscellaneous) faults have occurred in the cell blocks.

As described above, in embodiments of the present invention, the memory fault analyzer 254 may configure the actual physical layout according to the architectural information A_INFO of the cell blocks, and analyze the fault by checking the error locations corresponding to the error information ERR_INFO within the actual physical layout according to the data input/output information M_INFO. Accordingly, a fault boundary, in which occurrence of errors is capable, may be specified and the prediction rate of occurrences of UEs may be improved by the error correction capability that extends to the specified fault boundary.

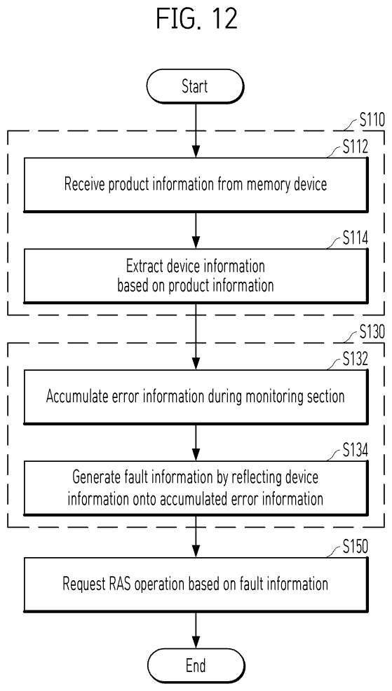

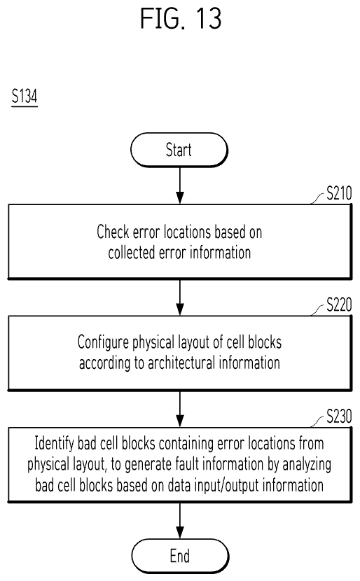

FIG. 12 is a flowchart for describing a fault analysis operation according to an embodiment of the present disclosure. FIG. 13 is a flowchart for describing a fault information generation operation S134 of FIG. 12 in more detail.

Referring to FIG. 12, an information storage 252 may store architectural information A_INFO and data input/output information M_INFO (at S110). In detail, the information storage 252 may store the device information for various devices in advance and receive unique product information from a memory device 100 during boot-up (at S112). The information storage 252 may extract corresponding device information MD_INFO based on the unique product information (at S114).

A memory fault analyzer 254 may perform a fault analysis operation (at S130). The memory fault analyzer 254 may accumulate the error information ERR_INFO generated by an ECC engine 230 during a monitoring section (at S132). The memory fault analyzer 254 may generate fault information F_INFO by reflecting the device information MD_INFO of the memory device 100 onto the accumulated error information ERR_INFO (at S134).

Referring to FIG. 13, the memory fault analyzer 254 may check error locations of data output from a plurality of cell blocks based on the accumulated error information ERR_INFO (at S210). The memory fault analyzer 254 may configure the physical layout of the cell blocks according to the architecture information A_INFO (at S220). That is, the memory fault analyzer 254 may configure the actual physical layout of the cell blocks based on a layout of word lines and bit lines of each cell block, a layout of redundancy word lines and bit lines of each cell block, the number of memory cells arranged per word line, the number of bit lines specified by one column address, a layout of bit line sense amplifiers of each cell block, and a layout of word line drivers of each cell block. In addition, the memory fault analyzer 254 may identify defective cell blocks including error locations from the physical layout to generate the fault information F_INFO related to the defective cell blocks according to the data input/output information M_INFO (at S230).

Referring back to FIG. 12, the RAS manager 256 may request a RAS operation to improve the reliability of the memory device according to the fault information F_INFO (at S150).

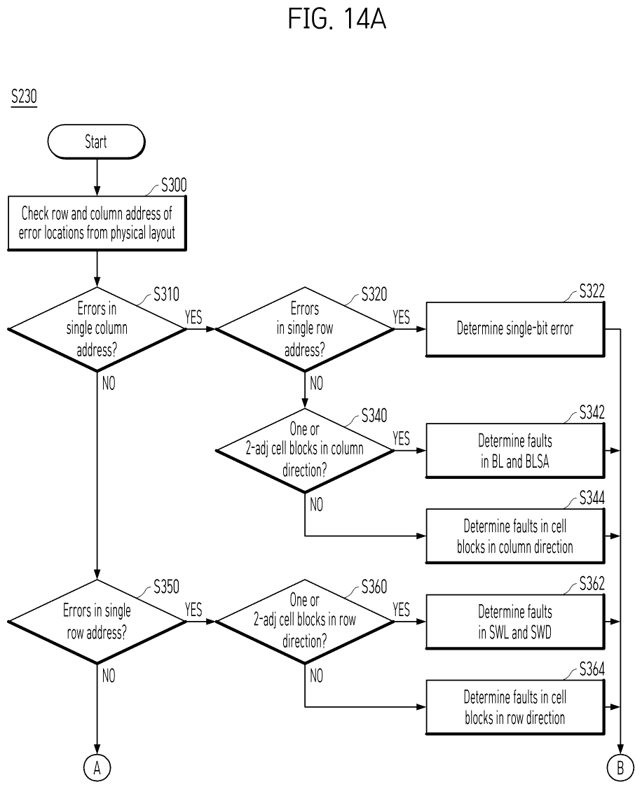

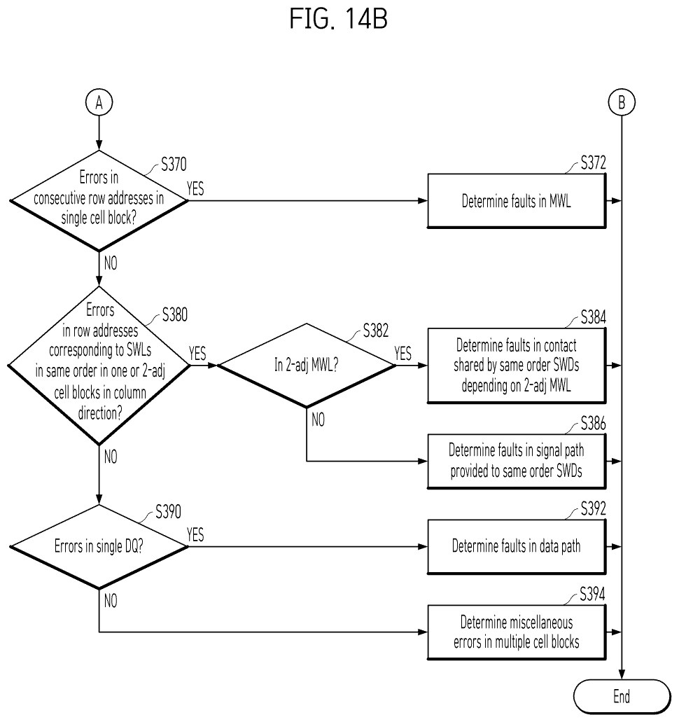

FIGS. 14A and 14B are flowcharts for describing a fault analysis operation S230 of FIG. 13 in more detail.

Referring to FIG. 14A, the memory fault analyzer 254 may check column addresses and row addresses of error locations from the physical layout (at S300).

When errors are located in a single column address and a single row address in the physical layout (“YES” of S310 & “YES” of S320), the memory fault analyzer 254 may determine a single-bit error corresponding to the single column address and the single row address and generate the fault information F_INFO accordingly (at S322).

When errors are located in a single column address but located in a plurality of row addresses, in a physical layout (“YES” of S310 & “NO” of S320), the memory fault analyzer 254 may check whether errors are located in one or two adjacent cell blocks in the column direction. When the errors are located in one or two adjacent cell blocks in the column direction (“YES” of S340), the memory fault analyzer 254 may determine a fault in a bit line or bit line sense amplifier corresponding to the single column address, and generate the fault information F_INFO accordingly (at S342). In some cases, as described in FIG. 11C, the memory fault analyzer 254 may determine that a fault in a bit line corresponding to the single column address when an error occurs in one defective cell block. In other cases, as described in FIG. 11D, the memory fault analyzer 254 may determine a fault in a bit line sense amplifier corresponding to the single column address when an error occurs in adjacent upper and lower defective cell blocks in the column direction.

When errors are located in a plurality of cell blocks, which are not adjacent to each other in the column direction (“NO” of S340), the memory fault analyzer 254 may determine faults in cell blocks arranged in the column direction (at S344).

When errors are located in a single row address but located in a plurality of column addresses, in a physical layout (“NO” of S310 & “YES” of S350), the memory fault analyzer 254 may check whether errors are located in one or two adjacent cell blocks in the row direction. When the errors are located in one or two adjacent cell blocks in the row direction (“YES” of S360), the memory fault analyzer 254 may determine a fault in a word line (i.e., sub-word line) or sub-word line driver corresponding to the single row address, and generate the fault information F_INFO accordingly (at S362). In some cases, as described in FIG. 11A, the memory fault analyzer 254 may determine a fault in one side of the word line or sub-word line driver corresponding to the single row address when an error occurs in one defective cell block. In other cases, as described in FIG. 11B, the memory fault analyzer 254 may determine a fault in both sides of the sub-word line driver corresponding to the single row address when an error occurs in two adjacent defective cell blocks.

When errors are located in a plurality of cell blocks, which are not adjacent to each other in the row direction (“NO” of S360), the memory fault analyzer 254 may determine faults in cell blocks arranged in the row direction (at S364).

Referring to FIG. 14B, when errors are located in a plurality of row addresses and a plurality of column addresses in a physical layout (“NO” of S310 & “NO” of S350), the memory fault analyzer 254 may check whether errors occur in consecutive row addresses equal to or less than a predetermined number of a single cell block (at S370). The predetermined number may be determined by the number of word lines connected to one main word line. As described in FIG. 11G, when errors occur in eight or less consecutive row addresses of one cell block (“YES” of S370), the memory fault analyzer 254 may determine a fault in a main word line corresponding to the consecutive row addresses and generate the fault information F_INFO accordingly (at S372).

When errors are located in a plurality of row addresses and a plurality of column addresses, and errors do not occur in consecutive row addresses equal to or less than a predetermined number of a single cell block, in a physical layout (“NO” of S310, “NO” of S350 & “NO” of S370), the memory fault analyzer 254 may check whether errors are located in row addresses corresponding to the same order of sub-word lines of one or two adjacent cell blocks in the column direction (at S380). For example, when eight sub-word lines are connected to one main word line, the memory fault analyzer 254 may check whether errors are located in each of the sub-word lines having eight intervals. In this case, when errors are located in the same order of sub-word lines disposed in two adjacent main word lines (“YES” of S380 & “YES” of S382), the memory fault analyzer 254 may determine a fault in a contact shared by sub-word line drivers for driving the same order of sub-word lines according to two adjacent main word lines MWL, as described in FIG. 11H, and generate the fault information F_INFO accordingly (at S384). When errors are located for each of the same order of sub-word lines in a plurality of main word lines (“YES” of S380 and “NO” of S382), the memory fault analyzer 254 may determine a fault in a signal path commonly provided to sub-word line drivers for driving the same order of sub-word lines, as described in FIG. 11I, and generate fault information F_INFO accordingly (at S386).

Further, when errors are located in a plurality of row addresses and a plurality of column addresses, in a physical layout (“NO” of S310 & “NO” of S350), and errors occur in one data pad (“YES” in S390), the memory fault analyzer 254 may determine a fault in a data pad or a related data path, to generate the fault information F_INFO accordingly (at S392). In this case, the memory fault analyzer 254 may determine a fault exists in a data path when errors occur the word lines of defective cell blocks arranged in a specific column direction, as described in FIG. 11E. The memory fault analyzer 254 may determine a fault exists in a data pad when errors occur in all cell blocks, as described in FIG. 11F.

Meanwhile, when any of the above conditions are not satisfied, the memory fault analyzer 254 may generate fault information F_INFO indicating that a number of unknown (or miscellaneous) faults have occurred in the cell blocks (at S384), as described in FIG. 11J.

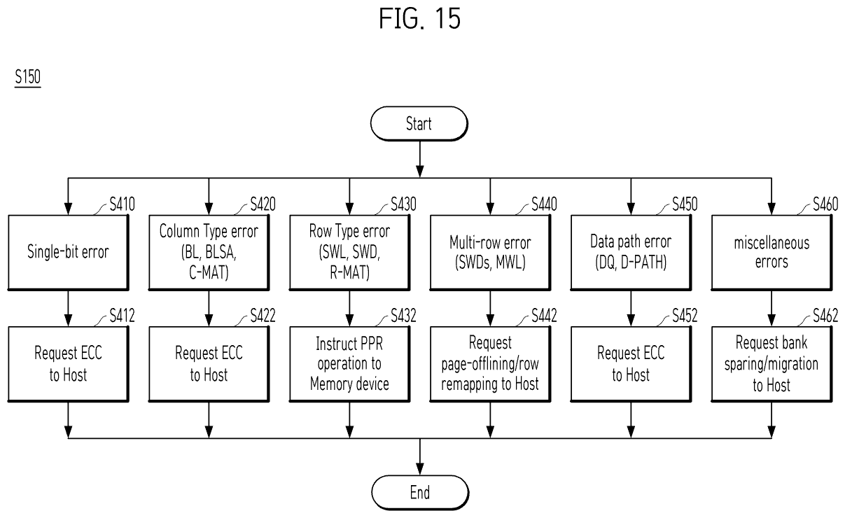

FIG. 15 is a flowchart for describing a RAS operation S150 in FIG. 12 in more detail.

Referring to FIG. 15, according to the fault information F_INFO notifying the single-bit error (at S410), the RAS manager 256 may request an error correction operation to the host (at S412).

According to the fault information F_INFO notifying a column type error involving a fault in a bit line, a bit line sense amplifier, or cell blocks arranged in the column direction (at S420), the RAS manager 256 may request an error correction operation to the host (at S422).

According to the fault information F_INFO notifying a row-type error involving a fault in a word line, a sub-word line driver, or cell blocks arranged in a row direction (at S430), the RAS manager 256 may instruct a post-package repair operation for repairing the corresponding word line to the memory device (at S432).

According to the fault information F_INFO notifying a multi-row type error involving a fault in a plurality of sub-word line drivers or a main word line (at S440), the RAS manager 256 may request a page offlining operation or a row remap operation to exclude the use of the addresses, to the host (at S442).

According to the fault information F_INFO notifying a multi-row type error involving a fault in a data pad or data path related to the data pad (at S450), the RAS manager 256 may request an error correction operation to the host (at S452).

According to the fault information F_INFO notifying a number of miscellaneous faults have occurred (at S460), the RAS manager 256 may request a bank sparing/migration operation for replacement of the bank, or a unuse of the memory device, to the host (at S462).

As described above, in an embodiment of the present invention, an actual physical layout may be configured according to the architectural information A_INFO of a plurality of cell blocks, and a fault may be analyzed by checking the error locations corresponding to the error information ERR_INFO within the actual physical layout according to the data input/output information M_INFO. Accordingly, by analyzing the faults, RAS operations may be optimized.

In the above, embodiments are described in which an error correction circuit is not included in the memory device 100, but the invention is not limited thereto. For example, when an error correction circuit is disposed in the memory device, the error correction circuit of the memory device may correct a single error, and a fault analysis engine (or device) may perform the remaining analysis operations except for a single error bit analysis, from among the above-described fault analysis operations, with the error-corrected data provided from the memory device.

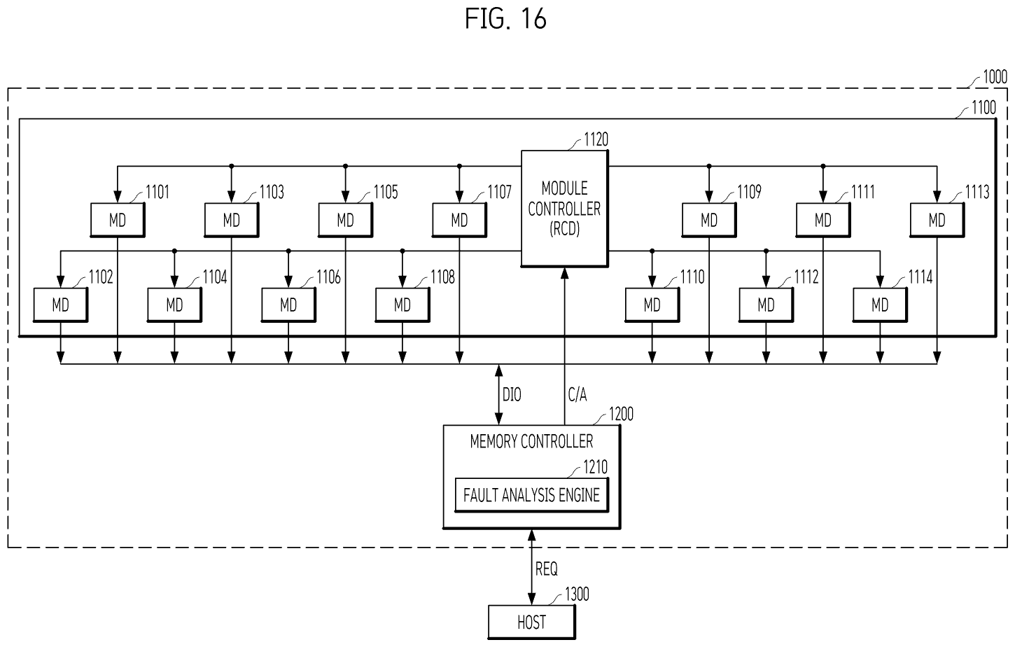

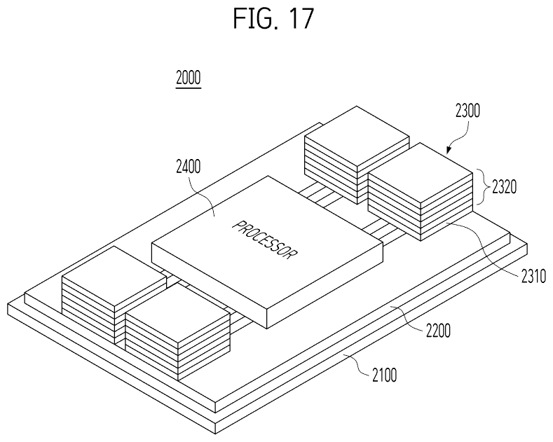

FIG. 16 is a block diagram illustrating a memory system including a memory module according to an embodiment of the present disclosure.

Referring to FIG. 16, a memory system 1000 may include a memory module 1100 and a memory controller 1200.

The memory controller 1200 may control the overall operation of the memory system 1000 and control a data exchange between a host 1300 and the memory module 1100. The memory controller 1200 may generate a command/address signal C/A according to a request REQ from the host 1300 to provide the command/address signal C/A to the memory module 1100, and provide data DIO corresponding to the request REQ from the host 1300 to the memory module 1100, and provide data DIO read from the memory module 1100 to the host 1300.

The memory module 1100 may include a plurality of memory devices (MD) 1101 to 1114 and a module controller (RCD) 1120. The module controller 1120 may include a known register clock driver. The module controller 1120 may control the memory devices 1101 to 1114 under the control of the memory controller 1200. For example, the module controller 1120 may receive the command/address signal C/A from the memory controller 1200 and control the data DIO to be written to the memory devices 1101 to 1114 or read from the memory devices 1101 to 1114.

Each of the memory devices 1101 to 1114 may correspond to a memory device 100 described above with reference to FIG. 3. That is, each of the memory devices 1101 to 1114 may include a plurality of banks each of which includes a plurality of cell blocks arranged in an array form. The module controller 1120 may store unique product information and provide the stored unique product information to the memory controller 1200 during boot-up. According to an embodiment, a separate chip may store unique product information and provide the stored unique product information to the memory controller 1200 during boot-up.

The memory controller 1200 may correspond to a memory controller 200 of FIG. 1. In particular, the memory controller 1200 may include a fault analysis engine 1210. The fault analysis engine 1210 may accumulate an error information of the memory devices 1101 to 1114 during a monitoring section, and analyze faults of the memory devices 1101 to 1114 by reflecting device information of the memory module 1100 onto the accumulated error information. The device information may include an architecture information of a plurality of cell blocks included in each bank, and data input/output information. The fault analysis engine 1210 may store the device information on various devices in advance and extract a corresponding device information based on the unique product information received from the memory device 100 during boot-up.

The fault analysis engine 1210 may check error locations of data output from the cell blocks of each bank based on the accumulated error information, configure a physical layout of the cell blocks based on the architectural information to identify defective cell blocks including the error locations, and analyze faults of the defective cell blocks from the physical layout according to the data input/output information. Accordingly, it is possible to improve the prediction rate of occurrences of UEs by analyzing faults based on actual architecture. The memory controller 1200 may request the host 1300 not to use a specific memory device from among the plurality of memory devices 1101 to 1114 based on the fault analysis result. The fault analysis engine 1210 may also be referred to as a fault analysis device, and may be disposed outside the memory controller 1200.

FIG. 17 is a block diagram illustrating a memory system including a stacked memory device according to an embodiment of the present disclosure.

Referring to FIG. 17, the memory system 2000 may include a package board/substrate 2100, an interposer 2200, one or more stacked memory devices 2300, and a processor 2400.

The package board/substrate 2100 may include a printed circuit board (PCB). The package board/substrate 2100 may be electrically connected to an external system board, main board, or module board through bumps.

The interposer 2200 may be formed on the package board/substrate 2100. The interposer 2200 may be a silicon substrate in which only wiring is formed.

The one or more stacked memory devices 2300 and the processor 2400 may be formed on the interposer 2200. The stacked memory devices 2300 and the processor 2400 may be disposed on the interposer 2200 to be spaced apart from each other. Meanwhile, although four stacked memory devices 2300 are illustrated in FIG. 17, the present invention is not limited thereto, and one or more stacked memory devices may be formed on the interposer 2200.

The processor 2400 may include a memory controller and a physical interface circuit. The memory controller may be configured to control the stacked memory devices 2300. The physical interface circuit may interface between the memory controller and the stacked memory devices 2300. The physical interface circuit may be an interface circuit that converts signals transferred from the memory controller into signals suitable for use in the stacked memory devices 2300 and outputs the signals transferred from the stacked memory devices 2300 into signals suitable for use in the memory controller. The processor 2400 may be one of various processors such as a micro-processing unit (MPU), a central processing unit (CPU), a general processing unit (GPU), and a host processing unit (HPU).

Each of the stacked memory devices 2300 may include a lower chip 2310 and one or more upper chips 2320 vertically stacked on the interposer 2200. An example of the stacked memory devices 2300 formed by stacking a plurality of chips as described above may be a high bandwidth memory (HBM). Through electrodes TSV are formed between the lower chip 2310 and the upper chips 2320, through which signals (i.e., commands, addresses, and data) may be transferred between the chips.

The lower chip 2310 may include a physical interface circuit for an interface with the memory controller. Each of the upper chips 2320 may correspond to the memory device 100 described in FIG. 3. That is, each of the upper chips 2320 may include a plurality of banks including a plurality of cell blocks each arranged in an array form. Each of the upper chips 2320 may store unique product information and provide the stored unique product information to the memory controller during boot-up. According to an embodiment, the lower chip 2310 may store unique product information and provide the stored unique product information to the memory controller during boot-up.

In an embodiment of the present invention, the memory controller may correspond to a memory controller 200 of FIG. 1. In particular, the memory controller may include a fault analysis engine, which accumulates an error information of the upper chips 2320 during a monitoring section and analyzes faults of the upper chips 2320 by reflecting device information of the stacked memory devices 2300 onto the accumulated error information. The memory controller may store the device information for various devices in advance, receive unique product information from the stacked memory devices 2300 for each boot-up, and extract corresponding device information based on the unique product information.

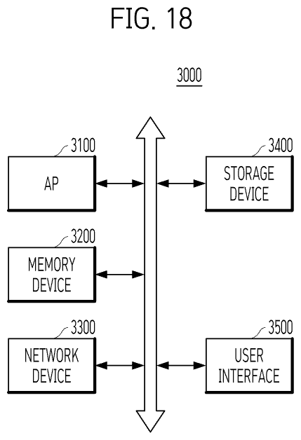

FIG. 18 is a block diagram illustrating a mobile system including a memory device according to an embodiment of the present disclosure.

Referring to FIG. 18, a mobile system 3000 may include an application processor (AP) 3100, a memory device 3200, a network device 3300, a storage device 3400, and a user interface 3500.

The application processor 3100 may drive components, an operating system (OS), or a user program included in the mobile system 3000. For example, the application processor 3100 may be provided as a system-on-chip (SoC).

The memory device 3200 may operate as a main memory, an operation memory, a buffer memory, or a cache memory of the mobile system 3000. The memory device 3200 may include a volatile random access memory such as DRAM, SDRAM, DDR SDRAM, DDR2 SDRAM, DDR3 SDRAM, LPDDR3 SDARM, LPDDR3 SDRAM, or a nonvolatile random access memory such as PRAM, ReRAM, MRAM, FRAM, etc. According to an embodiment, the memory device 3200 may be configured as a memory module 1100 described with reference to FIG. 16.

In an embodiment of the present invention, the memory device 3200 may correspond to a memory device 100 described in FIG. 3. That is, the memory device 3200 may include a plurality of banks each of which includes a plurality of cell blocks arranged in an array form. The memory device 3200 may store unique product information and provide the stored unique product information to the application processor 3100 during boot-up.

In an embodiment of the present invention, the application processor 3100 may correspond to a memory controller 200 of FIG. 1. In particular, the application processor 3100 may include a fault analysis engine that accumulates an error information of the memory device 3200 during a monitoring section and analyzes faults of the memory device 3200 by reflecting device information of the memory device 3200 onto the accumulated error information. The application processor 3100 may store the device information for various devices in advance, receive the unique product information from the memory device 3200 for each boot-up, and extract corresponding device information based on the unique product information. The fault analysis engine may also be referred to as a fault analysis device, and may be disposed outside the application processor 3100.

The network device 3300 may communicate with external devices. For example, the network device 3300 may support wireless communication such as Code Division Multiple Access (CDMA), Global System for Mobile Communication (GSM), Wideband CDMA (WCDMA), CDMA-2000, Time Division Multiple Access (TDMA), Long Term Evolution (LTE), Wimax, WLAN, UWB, Bluetooth, Wi-Fi, etc. For example, the network device 3300 may be included in the application processor 3100.

The storage device 3400 may store data. For example, the storage device 3400 may store data received from the application processor 3100. Alternatively, the storage device 3400 may transmit the stored data to the application processor 3100. For example, the storage device 3400 may be implemented as a nonvolatile semiconductor memory device such as a phase-change RAM (PRAM), a magnetic RAM (MRAM), a resistive RAM (RRAM), a NAND flash, a NAND flash, and a three-dimensional NAND flash.

While the present disclosure has been described with respect to the specific embodiments, it will be apparent to those skilled in the art that various changes and modifications may be made without departing from the spirit and scope of the invention as defined in the following claims. Furthermore, the embodiments may be combined to form additional embodiments.

What is claimed is:

1. A memory system, comprising:
at least one memory device disposed along a first direction and a second direction, configured to include a plurality of cell blocks that share word line drivers with adjacent cell blocks in the first direction, to share bit line sense amplifiers with adjacent cell blocks in the second direction, and to input/output data of the plurality of cell blocks through a plurality of data pads; and
a fault analysis device configured to analyze a fault of the memory device by accumulating an error information from the memory device and reflecting device information, including architectural information on the plurality of cell blocks and data input/output information, onto the accumulated error information.

2. The memory system of claim 1, wherein the architectural information includes:
one or more selected from a layout of word lines and bit lines of each cell block, a layout of redundancy word lines and bit lines of each cell block, a number of memory cells arranged per word line, a number of bit lines specified by one column address, a layout of bit line sense amplifiers of each cell block, and a layout of word line drivers of each cell block.

3. The memory system of claim 1, wherein the data input/output information includes:
a mapping information between the plurality of data pads and the plurality of cell blocks according to a data width option and a burst length.

4. The memory system of claim 3, wherein the mapping information includes:
one or more selected from a data pad (DQ) aligned structure in which data output from one cell block are output through one corresponding data pad during the burst length, a burst length (BL) aligned structure in which data output from one cell block are output through all data pads during one or more unit bursts of the burst length, and a mixed aligned structure of the DQ aligned structure and the BL aligned structure.

5. The memory system of claim 1, wherein the memory device includes a plurality of banks, each of the plurality of banks is the plurality of cell blocks.

6. The memory system of claim 1, wherein the fault analysis device is configured to:
check error locations of data output from the plurality of cell blocks based on the accumulated error information,
configure a physical layout of the plurality of cell blocks based on the architectural information to identify bad cell blocks including the error locations, and analyze faults of the bad cell blocks according to the data input/output information.

7. The memory system of claim 1, wherein, based on information on the analyzed fault, the fault analysis device instructs the memory device to perform a post package repair operation, or requests an error correction operation, a page offlining operation, a row remap operation, a bank sparing/migration operation, or an unuse of the memory device to a host.

8. A fault analysis device, comprising:
a memory fault analyzer configured to analyze a fault of a memory device by accumulating an error information from the memory device and reflecting device information including architectural information on a plurality of cell blocks and data input/output information, onto the accumulated error information, the memory device being disposed along a first direction and a second direction, including the plurality of cell blocks that share word line drivers with adjacent cell blocks in the first direction and share bit line sense amplifiers with adjacent cell blocks in the second direction, and inputting/outputting data of the plurality of cell blocks through a plurality of data pads; and
a reliability, accessibility, and serviceability (RAS) manager configured to perform an operation of improving a reliability of the memory device based on information on the analyzed fault.

9. The fault analysis device of claim 8, further comprising:
an information storage configured to store the device information in advance, and receive unique product information from the memory device during boot-up to extract a corresponding device information based on the unique product information.

10. The fault analysis device of claim 8, wherein the memory fault analyzer is configured to:
check error locations of data output from the plurality of cell blocks based on the accumulated error information,
configure a physical layout of the plurality of cell blocks based on the architectural information to identify bad cell blocks including the error locations, and
analyze faults of the bad cell blocks according to the data input/output information and generate a fault information.

11. The fault analysis device of claim 10, wherein, when errors are located in a single column address and a single row address in the physical layout, the memory fault analyzer generates the fault information notifying a single-bit error.

12. The fault analysis device of claim 10, wherein, when errors are located in a single column address of one or two adjacent cell blocks in the second direction in the physical layout, the memory fault analyzer generates the fault information notifying a fault in a bit line or bit line sense amplifier corresponding to the single column address.

13. The fault analysis device of claim 10, wherein, when errors are located in a single row address of one or two adjacent cell blocks in the first direction in the physical layout, the memory fault analyzer generates the fault information notifying a fault in a word line or word line driver corresponding to the single row address.

14. The fault analysis device of claim 10, wherein, when errors occur in consecutive row addresses equal to or less than a predetermined number of a single cell block in the physical layout, the memory fault analyzer generates the fault information notifying a fault in a main word line corresponding to the consecutive row addresses.

15. The fault analysis device of claim 10, wherein, when errors are located in the same order of word lines disposed in two adjacent main word lines in the physical layout, the memory fault analyzer generates the fault information notifying a fault in a contact shared by word line drivers for driving the same order of the word lines.

16. The fault analysis device of claim 10, wherein, when errors are located for each of the same order of word lines in a plurality of main word lines in the physical layout, the memory fault analyzer generates the fault information notifying a fault in a signal path commonly provided to word line drivers for driving the same order of the word lines.

17. The fault analysis device of claim 10, wherein, when data including errors are input/output through one data pad in the physical layout, the memory fault analyzer generates the fault information notifying a fault in a data pad and a data path related thereto.

18. The fault analysis device of claim 8, wherein, based on information on the analyzed fault, the RAS manager instructs the memory device to perform a post package repair operation, or requests an error correction operation, a page offlining operation, a row remap operation, a bank sparing/migration operation, or an unuse of the memory device to a host.

19. A fault analysis method, comprising:
accumulating an error information from at least one memory device that is disposed along a first direction and a second direction and includes a plurality of cell blocks that share word line drivers with adjacent cell blocks in the first direction and share bit line sense amplifiers with adjacent cell blocks in the second direction, and that inputs/outputs data of the plurality of cell blocks through a plurality of data pads;
checking error locations of data output from the plurality of cell blocks based on the accumulated error information;
configuring a physical layout of the plurality of cell blocks based on architectural information of the plurality of cell blocks; and
identifying bad cell blocks including the error locations from the physical layout, and generating a fault information on the bad cell blocks according to data input/output information.

20. The fault analysis method of claim 19, further comprising:
storing device information in advance, and receiving unique product information from the memory device during boot-up to extract the architectural information and the data input/output information based on the unique product information.

21. The fault analysis method of claim 19, wherein the generating a fault information includes:
when errors are located in a single column address and a single row address in the physical layout,
generating the fault information notifying a single-bit error; and
requesting an error correction operation to a host according to the fault information.

22. The fault analysis method of claim 19, wherein the generating a fault information includes:
when errors are located in a single column address of one or two adjacent cell blocks in the second direction in the physical layout,
generating the fault information notifying a fault in a bit line or bit line sense amplifier corresponding to the single column address; and
requesting an error correction operation to a host according to the fault information.

23. The fault analysis method of claim 19, wherein the generating a fault information includes:
when errors are located in a single row address of one or two adjacent cell blocks in the first direction in the physical layout,
generating the fault information notifying a fault in a word line or word line driver corresponding to the single row address; and
instructing the memory device to perform a post package repair operation.

24. The fault analysis method of claim 19, wherein the generating a fault information includes:
when errors occur in consecutive row addresses equal to or less than a predetermined number of a single cell block in the physical layout,
generating the fault information notifying a fault in a main word line corresponding to the consecutive row addresses; and
requesting a page offlining operation or a row remap operation to a host according to the fault information.

25. The fault analysis method of claim 19, wherein the generating a fault information includes:
when errors are located in the same order of word lines disposed in two adjacent main word lines in the physical layout,
generating the fault information notifying a fault in a contact shared by word line drivers for driving the same order of the word lines; and
requesting a page offlining operation or a row remap operation to a host according to the fault information.

26. The fault analysis method of claim 19, wherein the generating a fault information includes:
when errors are located for each of the same order of word lines in a plurality of main word lines in the physical layout,
generating the fault information notifying a fault in a signal path commonly provided to word line drivers for driving the same order of the word lines and
requesting a page offlining operation or a row remap operation to a host according to the fault information.

27. The fault analysis method of claim 19, wherein the generating a fault information includes:
when data including errors are input/output through one data pad in the physical layout,
generating the fault information notifying a fault in a data pad and a data path related thereto; and
requesting an error correction operation to a host according to the fault information.
